(19) United States
(12) Patent Application Publication
(10) Pub. No.: US 2026/0360439 A1
(43) Pub. Date: Nov. 12, 2026

(54) ERASE OPERATIONS IN FERROELECTRIC MEMORY DEVICES

(71) Applicant: CCSH Corporation, Wuhan (CN)

(72) Inventors: Tao YANG, Wuhan (CN); Zhuangzhuang LIN, Wuhan (CN); Lei LIU, Wuhan (CN); Wenxi ZHOU, Wuhan (CN); Zhiliang XIA, Wuhan (CN)

(21) Appl. No.: 19/372,352

(22) Filed: Oct. 29, 2025

(30) Foreign Application Priority Data
May 9, 2025 (CN) 202510595825.0

(51) Int. Cl. G11C 16/16; G11C 16/04; G11C 16/30

(52) U.S. Cl. CPC G11C 16/16; G11C 16/0483; G11C 16/30

(57) ABSTRACT

Systems, devices, and methods for erasing a ferroelectric NAND device are provided. In one aspect, a method includes: erasing a first cell string of a memory block of the ferroelectric NAND device; and after erasing the first cell string, erasing a second cell string of the memory block. The ferroelectric NAND device includes a plurality of memory blocks including the memory block, and the memory block includes a plurality of cell strings including the first cell string and the second cell string.

### CROSS-REFERENCE TO RELATED APPLICATIONS

This application claims priority to Chinese Patent Application No. 202510595825.0, filed on May 09, 2025, which is hereby incorporated by reference in its entirety.

### TECHNICAL FIELD

The present disclosure relates to ferroelectric memory devices.

### BACKGROUND

Semiconductor devices may be classified into non-volatile memory devices, such as flash memory devices, ferroelectric NAND devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing erase operations in ferroelectric memory devices (e.g., ferroelectric NAND devices), for example, at a memory string level.

One aspect of the present disclosure features a method of erasing a ferroelectric NAND device, the method including: erasing a first cell string of a memory block of the ferroelectric NAND device; and after erasing the first cell string, erasing a second cell string of the memory block, where the ferroelectric NAND device includes a plurality of memory blocks including the memory block, and the memory block includes a plurality of cell strings including the first cell string and the second cell string.

In some implementations, erasing the first cell string of the memory block includes applying a gate-induced drain leakage (GIDL) voltage to a first GIDL line corresponding to the first cell string, and erasing the second cell string of the memory block includes applying the GIDL voltage to a second GIDL line corresponding to the second cell string.

In some implementations, erasing the first cell string includes: applying a first voltage to the second GIDL line, the first voltage being greater than the GIDL voltage; or applying, during a first phase, a second voltage to the second GIDL line, and floating, during a second phase after the first phase, the second GIDL line.

In some implementations, applying the GIDL voltage to the first GIDL line includes: applying, during a third phase, a third voltage to the first GIDL line; and floating, during a fourth phase after the third phase, the first GIDL line.

In some implementations, the first GIDL line is between a bit line and word lines, and erasing the first cell string includes: applying an erase voltage to the bit line, the erase voltage being greater than the GIDL voltage; and performing one of: applying a fourth voltage to a third GIDL line that is between the word lines and a source line, the third GIDL line corresponding to the first cell string; or applying, during a fifth phase, a fifth voltage to the third GIDL line, and floating, during a sixth phase after the fifth phase, the third GIDL line to generate a floating voltage on the third GIDL line.

In some implementations, the third phase overlaps with the fifth phase, and the third phase is longer than the fifth phase.

In some implementations, at least one of the fourth voltage or the floating voltage of the third GIDL line is greater than the GIDL voltage.

In some implementations, erasing the first cell string includes: applying, during a seventh phase, a bottom select gate (BSG) voltage to a first BSG line that corresponds to the first cell string and a second BSG line that corresponds to the second cell string; and floating, during an eighth phase after the seventh, the first BSG line and the second BSG line.

In some implementations, erasing the first cell string includes: applying, during a ninth phase, a third BSG line that is between the word lines and the first BSG line, the third BSG line corresponding to the first cell string; and floating, during a tenth phase after the ninth phase, the third BSG line, where a voltage of the third BSG line is smaller than a voltage of the first BSG line, the voltage of the first BSG line is smaller than a voltage of the third GIDL line, and the voltage of the third GIDL line is smaller than the erase voltage, and where the voltage of the third GIDL includes one of the fourth voltage or the floating voltage.

In some implementations, the first GIDL line is between word lines and a source line, and where erasing the first cell string includes: applying an erase voltage to the source line, the erase voltage being greater than the GIDL voltage; and performing one of: applying a first voltage to a third GIDL line that is between the word lines and a bit line, the third GIDL line corresponding to the first cell string; or applying, during a first phase, a second voltage to the third GIDL line, and floating, during a second phase after the first phase, the third GIDL line to generate a floating voltage on the third GIDL line.

In some implementations, at least one of the first voltage or the floating voltage of the third GIDL line is greater than the GIDL voltage.

In some implementations, the first GIDL line is isolated from the second GIDL line.

In some implementations, erasing the first cell string includes: applying an erase voltage to a bit line and a source line, the erase voltage being greater than the GIDL voltage; and applying the GIDL voltage to a third GIDL line corresponding to the first cell string, the first GIDL line and the third GIDL line being on opposite sides of word lines, respectively.

In some implementations, the method includes erasing a plurality of first cell strings of the memory block by applying the GIDL voltage to at least one first GIDL line corresponding to the plurality of first cell strings, the plurality of first cell strings including the first cell string, the at least one first GIDL line including the first GIDL line; and after erasing the plurality of first cell strings, erasing a plurality of second cell strings of the memory block by applying the GIDL voltage to at least one second GIDL line, the plurality of second cell strings including the second cell string, the at least one second GIDL line including the second GIDL line, where the at least one first GIDL line is isolated from the at least one second GIDL line.

In some implementations, the method includes applying a word line voltage to a word line, the word line voltage being smaller than the GIDL voltage; and applying an erase voltage to at least one of a bit line or a source line, the erase voltage being greater than the GIDL voltage.

Another aspect of the present disclosure features a ferroelectric NAND device, including: a plurality of memory blocks, a memory block of the plurality of memory blocks including a plurality of cell strings including a first cell string and a second cell string; and a peripheral circuit coupled to the memory block of the plurality of memory blocks, where the peripheral circuit is configured to perform an erase operation by: erasing the first cell string; and after erasing the first cell string, erasing the second cell string.

In some implementations, for erasing the first cell string of the memory block, the peripheral circuit is configured to apply a gate-induced drain leakage (GIDL) voltage to a first GIDL line corresponding to the first cell string, and for erasing the second cell string of the memory block, the peripheral circuit is configured to apply the GIDL voltage to a second GIDL line corresponding to the second cell string.

In some implementations, for erasing the first cell string, the peripheral circuit is configured to: apply a first voltage to the second GIDL line, the first voltage being greater than the GIDL voltage; or apply, during a first phase, a second voltage to the second GIDL line, and floating, during a second phase after the first phase, the second GIDL line.

In some implementations, the first GIDL line is between a bit line and word lines, where for erasing the first cell string, the peripheral circuit is configured to: apply an erase voltage to the bit line, the erase voltage being greater than the GIDL voltage; and perform one of applying a third voltage to a third GIDL line that is between the word lines and a source line, the third GIDL line corresponding to the first cell string, the third voltage being greater than the GIDL voltage; or applying, during a third phase, a fourth voltage to the third GIDL line, and floating, during a fourth phase after the third phase, the third GIDL line.

In some implementations, the peripheral circuit is configured to: erase a plurality of first cell strings of the memory block by applying the GIDL voltage to at least one first GIDL line, the plurality of first cell strings including the first cell string, the at least one first GIDL line including the first GIDL line; and after erasing the plurality of first cell strings, erase a plurality of second cell strings of the memory block by applying the GIDL voltage to at least one second GIDL line, the plurality of second cell strings including the second cell string, the at least one second GIDL line including the second GIDL line. The at least one first GIDL line is isolated from the at least one second GIDL line.

Another aspect of the present disclosure features a ferroelectric NAND device, including: a plurality of memory blocks, a memory block of the plurality of memory blocks including a plurality of cell strings including a first cell string and a second cell string; and a peripheral circuit coupled to the memory block of the plurality of memory blocks, where the peripheral circuit is configured to perform an erase operation by: erasing the first cell string; and after erasing the first cell string, erasing the second cell string; and a controller coupled to the ferroelectric NAND device and configured to operate the ferroelectric NAND device.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a diagram illustrating a polarization direction in a ferroelectric memory cell under different voltages.

FIG. 1B illustrates a diagram for a multi-level cell (MLC) in a ferroelectric memory device configured to store two bits of data with different threshold voltage levels.

FIG. 1C illustrates a schematic circuit diagram of an example ferroelectric memory string.

FIG. 1D illustrates an example 3D semiconductor device with a control structure and a memory structure.

FIG. 1E illustrates an example capacitor structure of the example 3D semiconductor device of FIG. 1D.

FIGS. 2A-2B illustrate isometric views of an example of a ferroelectric memory block.

FIG. 2C illustrates an isometric view of another example of a ferroelectric memory block.

FIG. 3A illustrates an example of a voltage diagram of a first string in a top erase operation of erasing the first string using a first top GIDL line.

FIG. 3B illustrates an example of a voltage diagram of a second string in the top erase operation of FIG. 3A.

FIG. 4A illustrates an isometric view of another ferroelectric memory block.

FIG. 4B illustrates an isometric view of the ferroelectric memory block of FIG. 2C in a bottom erase operation.

FIG. 5A illustrates an example of a voltage diagram of a first string group in a bottom erase operation of erasing the first string group using a first bottom GIDL line.

FIG. 5B illustrates an example of a voltage diagram of a second string group in the bottom erase operation of FIG. 5A.

FIG. 6A illustrates an example of a voltage diagram of a first string group in a top and bottom erase operation for erasing the first string group using both a first top GIDL line and a first bottom GIDL line.

FIG. 6B illustrates an example of a voltage diagram of a second string group in the top and bottom erase operation of FIG. 6A.

FIG. 7 illustrates a flowchart of an example of a method of erasing a ferroelectric NAND device.

FIG. 8 illustrates a block diagram of a system having one or more semiconductor devices.

Like reference numbers and designations in the various drawings indicate like elements. It is to be understood that the various exemplary implementations shown in the figures are merely illustrative representations and are not necessarily drawn to scale.

### DETAILED DESCRIPTION

A memory device, such as a ferroelectric NAND device, can include one or more memory blocks. A memory block can include one or more memory strings. In some cases, ferroelectric memory cells can be erased at a block level. Erasing a target data in a memory block (e.g., a selected memory block) may involve copying and moving the remaining data (e.g., data to be retained) from the selected memory block to another block. Once the selected memory block is erased, the remaining data can be then moved back into the selected memory block. However, due to the process of copying, moving and restoring data, erasing at a block level may increase the burden on system data management, consume additional power, and increase latency. Decreasing the burden on the system data management and reduce power consumption during the erase operation can be challenging.

Implementations of the present disclosure provide ferroelectric NAND devices and methods to erase ferroelectric NAND devices. In some implementations, a method includes: erasing a first cell string of a memory block of the ferroelectric NAND device; and after erasing the first cell string, erasing a second cell string of the memory block. The ferroelectric NAND device includes a plurality of memory blocks including the memory block, and the memory block includes a plurality of cell strings including the first cell string and the second cell string.

Implementations of the present disclosure can provide one or more of the following technical advantages, effect, and/or benefits. For example, the techniques described in the present disclosure allow for erasing ferroelectric memory cells at a string level or at a finger level. A finger can include two or more memory strings but be smaller than a block. In some implementations, an individual string or an individual finger can be erased by applying a gate-induced drain leakage (GIDL) voltage (e.g., through a hold and release process) to the corresponding GIDL line, while GIDL lines of the unselected strings or unselected fingers in the same block can be either floating or applied with a voltage greater than the GIDL voltage to avoid being erased. Additionally, the techniques allow for an erase operation using a top GIDL line, an erase operation using a bottom GIDL line, or an erase operation using both the top and bottom GIDL line. Erasing the ferroelectric memory cell at a string level or a finger level can simplify the erase operation by easing the need to copy, move and retore data in unselected strings or fingers. Instead, only the unselected data (e.g., the data that is not intended for erase) within the selected string or finger are copied, moved and restored. This can decrease the burden on the system data management, reduce power consumption, and/or reduce latency.

Besides ferroelectric NAND devices, the techniques implemented herein can be also applied to other types of ferroelectric devices. The techniques can be also applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

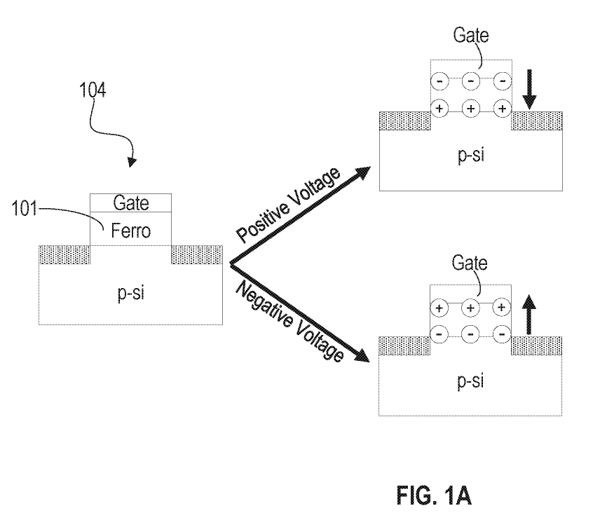

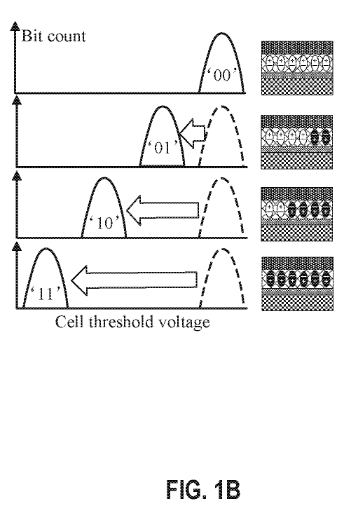

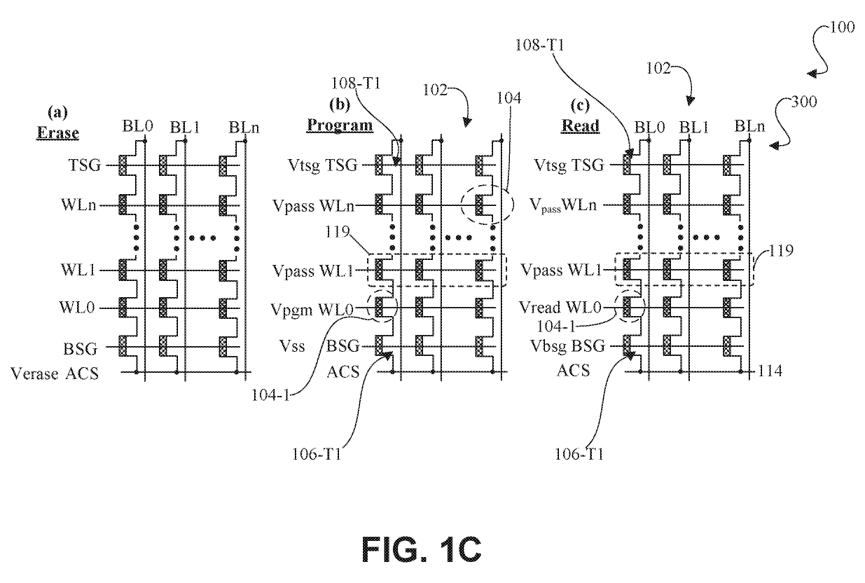

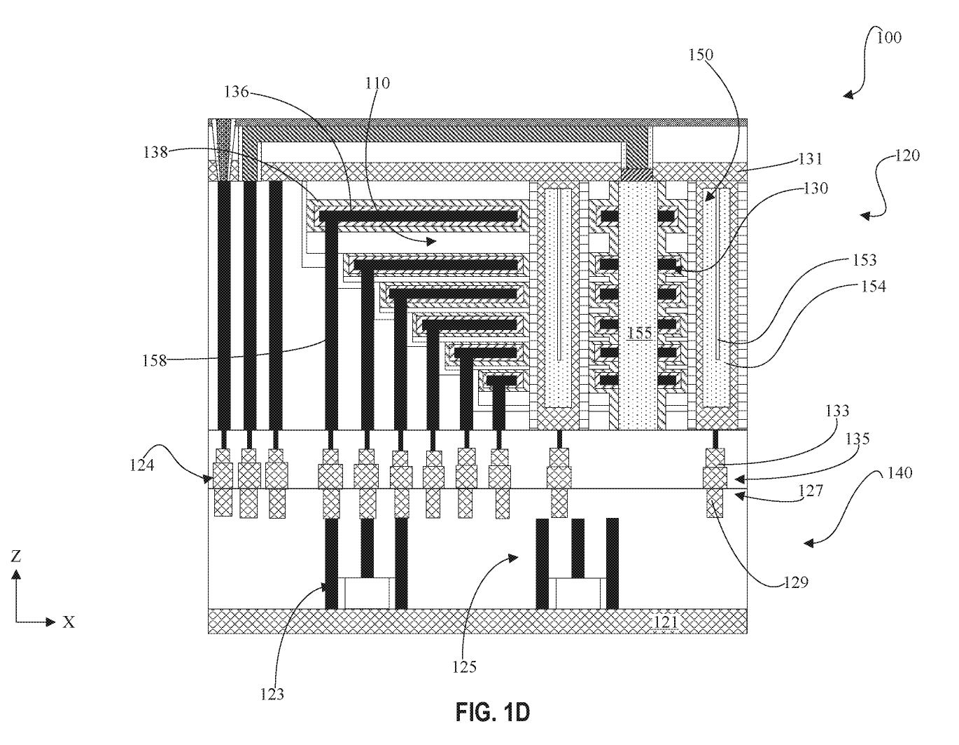

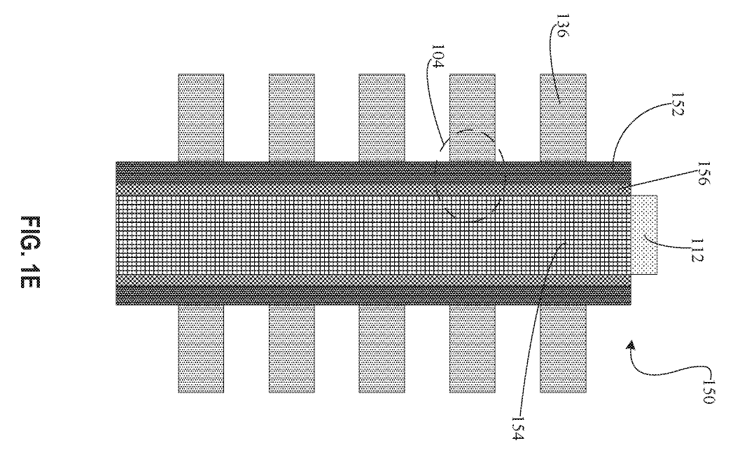

FIG. 1A illustrates a diagram illustrating a polarization direction in a ferroelectric memory cell 104 under different voltage. Without being bound to any particular theory, a ferroelectric memory cell 104 can operate based on a ferroelectric layer 101 being able to retain polarization, and this polarization state can influence a threshold voltage of a transistor. With a p-type channel, when a positive voltage is applied to the gate of the ferroelectric memory cell, the ferroelectric layer 101 may polarize in a way such that it induces negative charges at the channel interface, which may effectively reduce the threshold voltage of the transistor. In contrast, when a negative voltage is applied to the gate of the ferroelectric memory cell, the ferroelectric layer 101 may polarize in an opposite direction, inducing positive charges at the channel interface. This may increase the threshold voltage. The stored polarization state may remain even after the voltage is removed.

FIG. 1B illustrates a diagram for a multi-level cell (MLC) in a ferroelectric memory device configured to store 2 bits of data with different threshold voltage levels. Without limiting to any particular theory, ferroelectricity is a property observed in non-centrosymmetric dielectric crystals that show a spontaneous electric polarization, where the direction of polarization can be changed by an externally applied electric field. In a ferroelectric material, some atoms in the unit cell may be misplaced to create a permanent electric dipole due to the distribution of electric charge. A macroscopic manifestation of the charge separation is the surface charge of the ferroelectric material, described by a ferroelectric polarization P. Ferroelectric materials, e.g., Lead Zirconate Titanate (PZT), Strontium Bismuth Tantalate (SrBi2Ta2O9 or SBT), Barium Titanate (BaTiO3), and PbTiO3, have a perovskite-type crystal structure, where the cation in the center of the unit cell has two positions, both being stable low-energy states. The two low-energy states correspond to two opposite directions of the electric dipole. Under an external electric field, the cation can move in the direction of the electric field. Thus, by applying an external electric field across the crystal, cation in the unit cell can be moved from one low-energy position to another low-energy position, and the direction of the electric dipole can be flipped if the applied electric field is high enough. As a result, the electric polarization P in the ferroelectric material can be aligned with the direction of the external electric field.

A ferroelectric memory cell (e.g., the ferroelectric memory cell 104 of FIG. 1C) can be a single-level cell (SLC) with two possible memory states that can store one bit of data. For example, the first memory state “0” can correspond to a first range of voltages, and the second memory state “1” can correspond to a second range of voltages. In some implementations, each ferroelectric memory cell 104 is a multi-level cell (MLC) that is capable of storing more than one bit of data in more than two memory states. For example, the MLC can store two bits per cell, three bits per cell (also known as triple-level cell (TLC)), or four bits per cell (also known as a quad-level cell (QLC)). Each MLC can be programmed to support a range of possible nominal storage values. In one example, if each MLC stores two bits of data, then the MLC can be programmed to one of three possible programming levels from an erased state by writing one of three possible nominal storage values to the cell. A fourth nominal storage value can be used for the erased state. F

FIG. 1B illustrates an MLC with 2 bits, e.g., including four states, “00,” “01,” “10,” and “11,” representing different configurations of polarization directions. For example, as illustrated in FIG. 1B, the “00” state can correspond to all or substantial all of the electric dipoles in a ferroelectric layer 101 aligning along a first direction and have a first threshold voltage; the “01” state can correspond to a small portion of the electric dipoles aligning along a second direction opposite to the first direction and have a second threshold voltage smaller than the first threshold voltage; the “10” state can correspond to a substantial portion of the electric dipoles aligning along the second direction and have a third threshold voltage smaller than the second threshold voltage; and the “00” state can corresponding to all or substantial all of the electric dipoles aligning along the second direction and have a fourth threshold voltage smaller than the third threshold voltage. It is to be noted that the threshold voltages associated with four different states in a ferroelectric memory cell 104 can be opposite to those of a NAND memory cell (e.g., a device where the cell’s threshold voltages depend on an amount of stored charges rather than polarizations of dipoles). For example, in a ferroelectric memory cell 104, the “00” state can correspond to the highest threshold voltage, while “11” state can correspond to the lowest threshold voltage. In contrast, in a NAND memory cell, the “00” state can correspond to the lowest threshold voltage, while the “11” state can correspond to the highest threshold voltage.

FIG. 1C illustrates a schematic circuit diagram of an example ferroelectric memory string 102. In some implementations, the memory string 102 also includes at least one field effect transistor (e.g., MOSFET) at each end, which is controlled by a lower select gate (BSG) 106 and a top select gate (TSG) 108, respectively. And the two respective transistors are referred to as bottom and top select transistors 106-T and 108-T. The vertically stacked ferroelectric memory cells 104 can be controlled by the word lines (WL) 136 (e.g., WL0, …, WLn). The drain terminal of the top select transistor 108-T can be connected to the bit line 112, and the source terminal of the lower select transistor 106-T can be connected to a doped source line region, e.g., from where an array common source (ACS) 114 can be formed. In some implementations, ACS 114 is applied with a positive voltage. In some implementations, ACS 114 is applied with a voltage that is slightly greater than Vss, e.g., between 0 V and 0.5 V, between 0 V and 1 V, or between 0 V and 2 V. In some implementations, multiple array common sources 114 can be electrically connected with each other and shared by the memory strings 102 in an entire memory block. Thus, in some implementations, the array common source 114 is also referred to as the common source line. In this example, the TSG 108 and BSG 106 need to be addressed coordinately to support reading, programing (e.g., writing) and inhibiting operations of a target memory cell (e.g., the ferroelectric memory cell 104-1).

In the ferroelectric memory array, read and write operations can be performed in a memory page 119, which includes memory cells sharing the same word line (e.g., WL 1 shown in FIG. 1C). In some implementations, the ferroelectric memory cell 104 is a single level cell (SLC), which can be programmed to a logic state of “0” or “1.” In some implementations, the ferroelectric memory cell 104 is a MLC with 2 bites, which can programmed to a logic state of “00”, “01,” “10,” and “11,” as shown in FIG. 1B.

In some implementations, initially, the ferroelectric layer 101 in each ferroelectric memory cell 104 can have zero polarization and can be set or reset to logic state “11” or “00.” At the logic state of “11,” the ferroelectric memory cell 104 can be set to a lower threshold voltage Vth_L, and the current flowing through the ferroelectric memory cells 104 between the source terminal (connected to the array common source 114) and the drain terminal (connected to the bit lines 112) can be at a higher level for a given bias on the word line. At the logic state of “00,” the ferroelectric memory cells 104 can be reset to the higher threshold voltage Vth_H, (e.g., Vth_H>Vth_L) and the current flowing through the ferroelectric memory cells 104 between the source terminal and the drain terminal can be at a lower level for a given bias on the word line. By measuring (e.g., reading) the current that flows through the source and drain terminals of a selected memory cell, the threshold voltage Vth_H or Vth_L and thereby the logic state (or programmed data) of the ferroelectric memory cell 104 can be determined accordingly. In some implementations, the higher and lower threshold voltages Vth_H and Vth_L can be in a range between about −3V to about 3V.

In some examples, as illustrated in diagram (c) of FIG. 1C, to read the data in the target memory cell 104-1 shown in FIG. 1C, which is coupled to the word line WL0 and the bit line BL0, the corresponding TSG 108-T1 and the BSG 106-T1 of a selected memory string 102 can be applied with a top select gate voltage Vtsg and a bottom select gate voltage Vbsg to switch on a corresponding top select transistor 108-T1 and a lower select transistor 106-T1. In this example, a current path through the ferroelectric memory cell 104-1 can be established for the selected memory string 102. The current flowing through the selected memory string 102 can be detected from the bit line (e.g., BL0) and the array common source 114 that are electrically coupled to the selected memory string 102.

In order to read the storage data in the target memory cell (e.g., the ferroelectric memory cell 104-1), the TSG of unselected memory strings can be applied with an off voltage (Voff) to switch off a corresponding top select transistor. A current path between the unselected memory string and bit line 112 can thereby be disconnected. In this example, storage data can be read from one memory cell 104 at a time.

In some implementations, the TSGs 108 and BSGs 106 of the unselected memory strings can also be applied with the top select gate voltage Vtsg and the bottom select gate voltage Vbsg, respectively, to switch on the corresponding top select transistors 108-T and lower select transistor 106-T, and to establish conductive paths between the bit lines 112 and the unselected memory strings. In this example, data stored in the ferroelectric memory cells 104 in the same memory page can be measured simultaneously at respective bit lines 112 by applying the reading voltage Vread at the shared word line WL0. In this example, storage data can be read simultaneously from all the memory cells 104 in one memory page (e.g., a memory page 119).

To read the target memory cell 104-1 in the selected memory string 102, a selected word line (e.g., word line WL0) can be applied with the read voltage Vread, while other word lines that are not selected can be applied with a pass voltage Vpass. The pass voltage Vpass can be higher than the highest threshold voltage of all the ferroelectric memory cells 104 such that all the other ferroelectric memory cells 104 on the selected memory string 102 can be fully switched on. The read voltage Vread applied on the selected word line WL0 can be adjusted for sensing (e.g., reading or measuring) the threshold voltage of the target memory cell 104-1. In some implementations, the read voltage Vread can have a value in between the lower and higher threshold voltages Vth_L and Vth_H, e.g., Vth_L<Vread<Vth_H. For example, if Vth_L=−2.5V and Vth_H=−1.5V, the read voltage Vread can be in a range between about −2.5V and about −1.5V. As an example, the read voltage Vread can be −2.0 V and the pass voltage Vpass can be 0 V. If the target memory cell 104-1 is at the logic state of “11” having the lower threshold voltage Vth_L, the target memory cell 104-1 can be switched on when applying the read voltage Vread=−2.0 V on the word line WL0. Then, the top and lower select transistors 108-T-2 and 106-T-2, and all the memory cells 104 in the selected memory string 102 are switched on. Higher level of current flows between the bit line BL0 and the array common source 114 with a conductive path having a lower resistance. If the target memory cell 104-1 is at the logic state of “00” with the higher threshold voltage Vth_H, the target memory cell 104-1 can be switched off when applying the read voltage Vread=−2.0 V on the word line WL0 as used in the example above. Under this operation condition, even though the top and lower select transistors 108-T1 and 106-T1, and all the other memory cells 104 of the selected memory string 102 are switched on, the target memory cell 104-1 is switched off. Lower level of current flows between the bit line BL0 and the array common source 114 with a conductive path having a higher resistance. By measuring the current at bit line BL0, the logic state of the target memory cell 104-1 can be determined.

During the current measurement, a sensing voltage Vsensing can be applied to the bit line BL0, while the array common source 114 can be grounded (e.g., kept at 0V). To avoid disturbing the polarization of the ferroelectric layer 101 in the ferroelectric memory cell 104, the read voltage Vread and the pass voltage Vpass should be less than the coercive voltage V. For example, in some implementations, if the coercive voltage Vc=3.0V, the read voltage Vread and the pass voltage Vpass can range between about -3.0V and about 3.0V. The sensing voltage Vsensing applied to the bit line for sensing (or reading) the current can be low enough without causing significant potential change in a channel layer. The resistance of the target memory cell 104-1 can be extracted from the measured current and the sensing voltage Vsensing. In some implementations, the sensing voltage Vsensing can be in a range between about 0.1V to about 0.5V. As described above, the logic states of “0” and “1” of the target memory cell 104-1, based on threshold voltages of Vth_H and Vth_L, can be determined accordingly.

As illustrated in diagram (b) of FIG. 1C, in some implementations, a ferroelectric memory cell 104 can be programmed. For illustration purpose, the target ferroelectric memory cells 104-1 will be used as an example in the subsequent discussions for simplicity. During a program phase, the selected word line WL0 that is coupled to the target ferroelectric memory cells 104-1 can be applied with a program voltage Vpgm, while unselected word lines can be applied with a pass voltage Vpass. The selected bit line can be applied with a first voltage (e.g., Vss), while unselected bit line can be applied with an inhibit voltage Vinhib greater than the first voltage. The corresponding TSG 108-T1 can be applied with top select gate voltage Vtsg to switch on the TSG 108-T1, while the unselected TSG can be applied with an off voltage. In some implementations, the off voltage is Vss. The corresponding BSG 106-T1 can be applied with an off voltage (e.g., Vss). The ACS can be applied with a ground voltage (e.g., Vss).

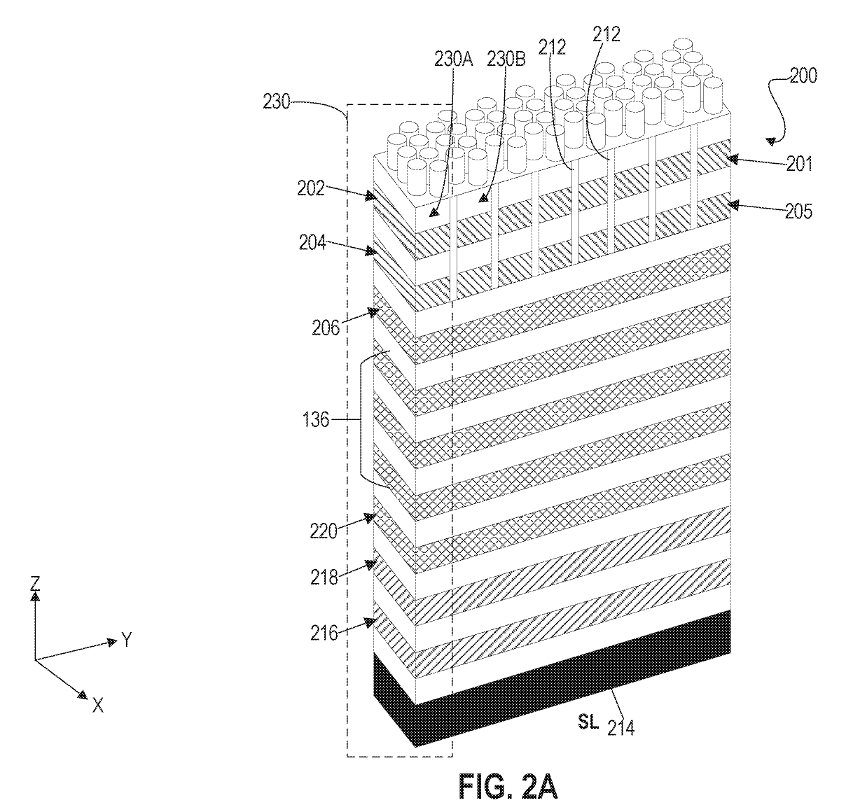

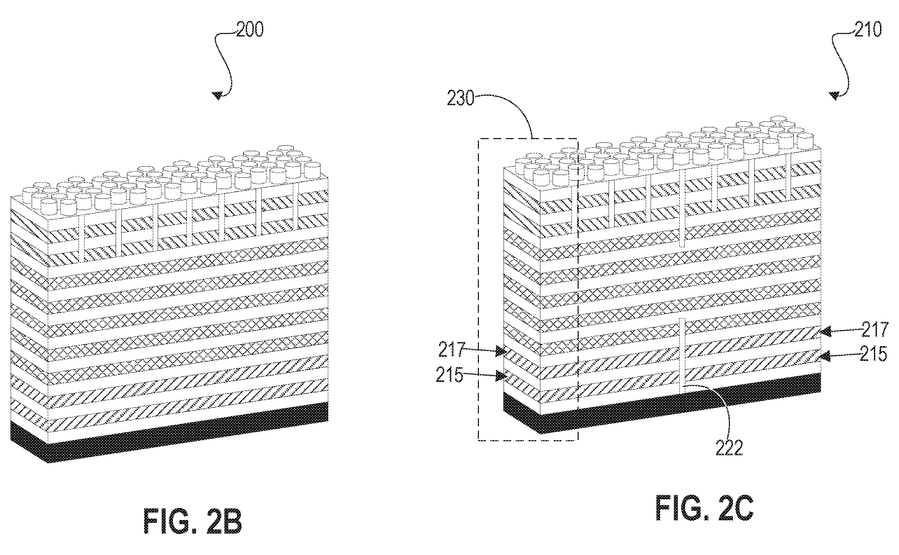

As shown in diagram (a) of FIG. 1C, in some implementations, multiple memory cells 104 can be erased. As described with further details below in reference to FIGS. 2A-6, the memory cells 104 can be erased at a string level.

FIG. 1D illustrates an example 3D ferroelectric memory device 100 with a control structure 140 and a memory structure 120. FIG. 1E illustrates an example channel structure of the 3D semiconductor device 100 of FIG. 1D. As used herein, whether one component (e.g., a layer or a device) is “on,”“above,”“over” or “below” another component (e.g., a layer or a device) of a device (e.g., 3D ferroelectric memory device 100) is determined relative to the structure or layer (e.g., control structure 140) in the z-direction (e.g., the vertical direction) when the structure or layer is positioned in the lowest tier of the device in the z-direction. The same notion for describing spatial relationships is applied throughout the present disclosure. For ease of description, reference will be made to both FIGS. 1D and 1E when describing the structure of the example 3D ferroelectric memory device 100.

The 3D memory device 100 represents an example of a non-monolithic 3D memory device. The term “non-monolithic” means that the components of 3D memory device 100 (e.g., peripheral circuit and memory array) can be formed separately on different substrates and then joined to form a 3D memory device.

3D memory device 100 can include a control structure (e.g., a first semiconductor structure 140) and a memory structure (e.g., a second semiconductor structure 120). 3D memory device 100 can further include an interconnection structure 124 between first and second semiconductor structures 140 and 120. First and second semiconductor structures 140 and 120 can be fabricated separately (and in parallel in some implementations) such that the thermal budget of fabricating one of first and second semiconductor structures 140 and 120 does not limit the processes of fabricating another one of first and second semiconductor structures 140 and 120. Moreover, a large number of interconnects (e.g., bonding contacts 129, 133 via hybrid bonding) can be formed through the interconnection structure to make direct, short, electrical connections between first semiconductor structure 140 and second semiconductor structure 120, as opposed to the long-distance chip-to-chip data bus on the circuit board, thereby eliminating chip interface delay and achieving high-speed I/O throughput with reduced power consumption. Data transfer between the array of 3D memory strings in second semiconductor structure 120 and the peripheral circuits 125 in control structure 140 can be performed through the interconnects (e.g., bonding contacts via hybrid bonding) across the interconnection structure 124. Furthermore, by vertically integrating first and second semiconductor structures 140 and 120, the chip size can be reduced, and the memory cell density can be increased.

The relative positions of stacked first and second semiconductor structures 140 and 120 and the interconnection structure 124 are not limited. In some implementations, second semiconductor structure 120 can be disposed above first semiconductor structure 140. Nevertheless, in such implementations, interconnection structure 124 can be also formed vertically between first and second semiconductor structures 140 and 120.

In some implementations, the control structure (e.g., a first semiconductor structure 140) includes peripheral circuits 125. The peripheral circuits 125 can be implemented, for example, with advanced logic processes (e.g., technology nodes of 90 nm, 80 nm, 65 nm, 55 nm, 45 nm, 40 nm, 32 nm, 28 nm, 22 nm, 20 nm, 16 nm, 14 nm, 10 nm, 7 nm, 5 nm, 3 nm, etc.) to achieve high speed. In some implementations, the peripheral circuits in the first semiconductor structure 140 are implemented using complementary metal-oxide-semiconductor (CMOS) technology.

In some implementations, the peripheral circuits 125 include any suitable digital, analog, and/or mixed-signal peripheral circuits used for facilitating the operation of 3D memory device 100. For example, the peripheral circuits 125 can include one or more of a page buffer, a decoder (e.g., a row decoder and a column decoder), a sense amplifier, a driver, a charge pump, a current or voltage reference, or any active or passive components of the circuits (e.g., transistors, diodes, resistors, or capacitors). The peripheral circuits 125 can include transistors 123 formed “on” a substrate 121, in which the entirety or part of the transistors 123 are formed in the substrate 121 and/or directly on the substrate 121. Isolation regions (e.g., shallow trench isolations (STIs)) and doped regions (e.g., source regions and drain regions of the transistors) can be formed in the substrate as well. The transistors 123 are high-speed with advanced logic processes, according to some implementations. In some implementations, the peripheral circuit(s) 125 may further include other circuits compatible with the advanced logic processes including logic circuits, such as processors and programmable logic devices (PLDs), or memory circuits, such as SRAM and DRAM.

In some implementations, first semiconductor structure 140 further includes an interconnect layer to transfer electrical signals to and from the peripheral circuits 125. The interconnect layer can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. The interconnect layer can further include one or more interlayer dielectric (ILD) layers (also known as “inter-metal dielectric (IMD) layers”) in which the interconnect lines and VIA contacts can form. That is, the interconnect layer can include interconnect lines and VIA contacts in multiple ILD layers. The interconnect lines and VIA contacts in the interconnect layer can include conductive materials including, but not limited to, tungsten (W), cobalt (Co), copper (Cu), aluminum (Al), silicides, or any combination thereof. The ILD layers in the interconnect layer can include one or more dielectric materials including, but not limited to, silicon oxide, silicon nitride, silicon oxynitride, low dielectric constant (low-k) dielectrics, or any combination thereof.

First semiconductor structure 140 can further include a bonding layer 127. The bonding layer 127 can include bonding contacts 129 and dielectrics electrically isolating the bonding contacts. Bonding contacts 129 can include conductive materials including, but not limited to, W, Co, Cu, Al, silicides, or any combination thereof. The remaining area of bonding layer can be formed with dielectrics including, but not limited to, silicon oxide, silicon nitride, silicon oxynitride, low-k dielectrics, or any combination thereof. Bonding contacts 129 and surrounding dielectrics in the bonding layer 127 can be used for hybrid bonding.

In some implementations, the memory structure (e.g., a second semiconductor structure 120) includes an array of 3D memory array. In some implementations, the second semiconductor structure 120 can be a ferroelectric memory device 100, described above in reference to FIGS. 1B and 1C.

Second semiconductor structure 120 can also include a bonding layer 135 that includes a plurality of bonding contacts 133 and dielectrics electrically isolating bonding contacts. The bonding contacts 133 of second semiconductor structure 120 can include conductive materials including, but not limited to, W, Co, Cu, Al, silicides, or any combination thereof. The remaining area of the bonding layer of the second semiconductor structure 120 can be formed with dielectrics including, but not limited to, silicon oxide, silicon nitride, silicon oxynitride, low-k dielectrics, or any combination thereof. The bonding contacts 133 and surrounding dielectrics in the bonding layer 135 of second semiconductor structure 120 can be used for hybrid bonding.

First semiconductor structure 140 can be bonded on top of second semiconductor structure 120 in a face-to-face manner. In some implementations, first and second semiconductor structures 140 and 120 can be bonded by hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously.

In some implementations, second semiconductor structure 120 further includes an interconnect layer to transfer electrical signals. The interconnect layer can include a plurality of interconnects, such as MEOL interconnects and BEOL interconnects. The interconnect layer can further include one or more ILD layers in which the interconnect lines and VIA contacts can form. The interconnect lines and VIA contacts in the interconnect layer can include conductive materials including, but not limited to W, Co, Cu, Al, silicides, or any combination thereof. The ILD layers in the interconnect layer can include one or more materials including, but not limited to, silicon oxide, silicon nitride, silicon oxynitride, low-k dielectrics, or any combination thereof.

In some implementations, 3D memory device 100 is a memory device in which memory cells are provided in the form of an array of memory strings (e.g., the ferroelectric memory string 102 of FIG. 1C). As shown in FIG. 1D, 3D memory device 100 can include a multi-layer stacked structure 130 disposed over substrate 131. In some implementations, substrate 131 includes silicon (e.g., single crystalline silicon, c-Si), silicon germanium (SiGe), gallium arsenide (GaAs), germanium (Ge), silicon-on-insulator (SOI), or any other suitable materials. The substrate 131 can be a thinned substrate with reduced thickness. Multi-layer stacked structure 130 includes alternately stacked dielectric layers 138 and conductive layers 136. The conductive layers 136 can also be referred to as gate lines 136 or word lines 136 in the present disclosure. The number of the pairs of conductive layers 136 and dielectric layers 138 can determine the number of memory cells in 3D memory device 100. As shown, conductive layers 136 and dielectric layers 138 can alternate in the vertical direction. In other words, except the ones at the top or bottom of multi-layer stacked structure 130, each conductive layer 136 can be sandwiched between two dielectric layers 138, and each dielectric layer 138 can be sandwiched between two conductive layers 136. Conductive layers 136 can include conductive materials, for example, including, but not limited to, W, Co, Cu, Al, polysilicon, doped silicon, silicides, or any combination thereof. Each conductive layer 136 can include, for example, a gate electrode surrounded by an adhesive layer and a gate dielectric layer. The gate electrode of conductive layer 136 can extend laterally as a word line, ending at one or more staircase structures 110 of multi-layer stacked structure 130. Dielectric layers 138 can include one or more dielectric materials, for example, including, but not limited to, silicon oxide, silicon nitride, silicon oxynitride, or any combination thereof.

The multi-layer stacked structure 130 can have a staircase structure 110. The staircase structure 110 of the 3D memory device can be formed along the Z direction (e.g., a vertical direction) and X direction (e.g., word line direction) with progressively truncated lengths of the conductive layers 136 along the word line direction, as illustrated in FIG. 1D. In some implementations, the dielectric layers 138 also have progressively truncated lengths along the word line direction. The conductive layers 136 can also be referred to as word lines 136 in the present disclosure.

3D memory device 100 can further include one or more word line contacts 158 extending in the second semiconductor structure 120 at different depths to connect corresponding conductive layers 136 in the staircase structure 110 of the multi-layer stacked structure 130. The word line contacts 158 can couple out corresponding conductive layers to a control circuit, e.g., a word line driver. In some implementations, the word line contacts include conductive materials, for example, including, but not limited to, W, Co, Cu, Al, polysilicon, doped silicon, silicides, or any combination thereof.

3D memory device 100 further includes channel structures 150 extending in the multi-layer stacked structure 130. In some implementations, as illustrated in FIG. 1E, each of the channel structures 150 can include a ferroelectric layer 152 (e.g., the ferroelectric layer 101 of FIG. 1A), a dielectric layer 156, and a channel layer 154. The dielectric layer 156 can be between the ferroelectric layer 152 and the channel layer 154. The ferroelectric layer 152 can be coupled to the conductive layers 136.

In some implementations, the ferroelectric layer 152 includes a ferroelectric material or an anti-ferroelectric material. In some implementations, ferroelectric layer 152 includes one or more dielectric materials, for example, including, but not limited to, Zirconate Titanate (PZT), Strontium Bismuth Tantalate (SBT), Zirconium-doped Hafnium Dioxide (Zr:HfO₂), Aluminum-doped Hafnium Dioxide (Al:HfO₂), Silicon-doped Hafnium Dioxide (Si: HfO₂), Diindium Triselenide (In₂Se₃), Indium Selenide (InSe), or Copper Indium Phosphorus Sulfide (CuInP₂S₆)., or any combination thereof. In some implementations, the channel layer 154 includes amorphous silicon, polycrystalline silicon, monocrystalline silicon, and/or any combination thereof. In some implementations, the dielectric layer 156 includes silicon oxide, silicon nitride, silicon oxynitride, high-k dielectric material (e.g., HfO₂, HfAlO, Al₂O₃), or any combination thereof.

In some implementations, the ferroelectric memory cell 104 (also referred to as the FeFET) can include a FeFET having a structure similar to a metal oxide semiconductor field effect transistor (MOSFET), where the gate (e.g., the conductive layer 136) and the channel (e.g., the channel layer 154) of the transistor can be separated by the ferroelectric layer 152. In some implementations, the dielectric layer 156 is used to reduce the possibility of material intermixing between the ferroelectric layer 152 and the channel layer 154. The effective gate dielectric of a FeFET can be the combination of the ferroelectric layer 152 and the dielectric layer 156. Thinner effective gate dielectric can provide better control of the channel layer 154 from the conductive layer 136. Thus, a thickness of the dielectric layer 156 can be in a range between about 5 nm and about 50 nm.

In some implementations, as illustrated in FIG. 1E, the channel layer 154 fills a center portion of the channel structure 150. In some other implementations, as illustrated in FIG. 1D, the channel structure 150 further includes a filling layer 153 in the center portion of the channel structure 150, and the filling layer 153 is at least partially surrounded by the channel layer 154. Therefore, the channel layer 154 may not fully fill the center portion of the channel structure 150. The filling layer 153 can include dielectric materials including, but not limited to, silicon oxide, silicon nitride, silicon oxynitride, or any combination thereof.

In some implementations, the ferroelectric memory cell 104 can further include a barrier layer (not shown in FIG. 1E) between the conductive layer 136 and the ferroelectric layer 152. The barrier layer can be disposed on a sidewall of a capacitor channel hole prior to disposing the ferroelectric layer 152. The barrier layer can be used to block the interactions between the ferroelectric layer 152 and the conductive layer 136. The barrier layer can have a thickness in a range between about 5 nm and about 50 nm. The barrier layer can include silicon oxide, silicon nitride, silicon oxynitride, high-k dielectric materials (e.g., HfO₂, Al₂O₃), and/or any combination thereof.

Referring back to FIG. 1D, 3D memory device 100 further includes one or more blocking structures 155 extending into multi-layer stacked structure 130. Each of blocking structures 155 can separate one subset of channel structures 150 from another subset of channel structures 150. In some implementations, blocking structure 155 includes a dielectric material, including, but not limited to, silicon oxide, silicon nitride, silicon oxynitride, or any combination thereof. In some implementations, blocking structure 155 includes a dielectric layer and a conductive layer.

3D memory device 100 further includes bit lines (e.g., as illustrated in FIG. 1E) coupled to one end of the channel layer 154. Bit lines 112 can be formed penetrating a dielectric layer disposed over the multi-layer stacked structure 130, according to some implementations. In some implementations, bit lines 112 can include bit line contacts formed by forming openings in another dielectric layer disposed over the bit line 112, followed by filling the openings with conductive materials such as W, Co, Cu, Al, Ti, TiN, Ta, TaN, doped silicon, silicides, or any combination thereof, and deposited by CVD, PVD, sputtering, evaporating, plating, or any combination thereof. In some implementations, bit lines 112 can be configured to read data stored in the memory cells of 3D memory device 100.

FIGS. 2A-2B illustrate isometric views of an example of a ferroelectric memory block 200. FIG. 2C illustrates an isometric view of another example of a ferroelectric memory block 210. The memory block 210 differs from the memory block 200 primarily in that the memory block 210 has a bottom cut structure 222. The ferroelectric memory block 200 can include a plurality of word lines 136. The ferroelectric memory block 200 can further include one or more TSG layers 204 and one or more top GIDL layers 202 between bit lines and the word lines 136. The top GIDL layers 202 can be between the bit lines (e.g., bit line 112 of FIGS. 1C and 1E) and the TSG layers 204 along Z direction. In some implementations, the memory block 200 includes one top GIDL layer 202 and two or more TSG layers 204.

In some implementations, the ferroelectric memory block 200 includes at least one dummy TSG layer 206 between the TSG layers 204 and the word lines 136. In some implementations, the top GIDL layer 202, TSG layer 204, and dummy TSG layer 206 have the same conductive material, e.g., doped polysilicon, or tungsten. In some implementations, the top GIDL layer 202, TSG layer 204, and dummy TSG layer 206 have different conductive materials. For example, the dummy TSG layer 206 can include tungsten, while the top GIDL layer 202 and TSG layer 204 can include doped polysilicon. The top GIDL layer 202, TSG layer 204, and dummy TSG layer 206 can be separated from one another by dielectric layers. The dielectric layers can include a material, including without limitation to, silicon oxide, silicon nitride, silicon oxynitride, or any combination thereof.

In some implementations, each top GIDL layer 202 includes a plurality of top GIDL lines 201 that are arranged along a lateral direction (e.g., Y direction). Adjacent top GIDL lines 201 can be separated by a top cut structure 212. Similarly, each TSG layer 204 can include a plurality of TSG lines 205 that are arranged along a lateral direction (e.g., Y direction). Adjacent TSG lines 205 can also be separated by the top cut structure 212. In other words, the top cut structure 212 can extend vertically into both top GIDL layers 202 and TSG layers 204 to divide each top GIDL layer 202 into a plurality of top GIDL lines 201 and divide each TSG layer 204 into a plurality of TSG lines 205. The top cut structure 212 can include a dielectric material, e.g., silicon oxide, silicon nitride, silicon oxynitride, or any combination thereof.

In some implementations, a number of the top GIDL lines 201 is equal to a number of TSG lines 205. Each top GIDL line 201 and/or each TSG line 205 can select a respective memory string 230. As shown in FIG. 2A, the memory block 200 can include a plurality of memory strings 230, e.g., a first memory string 230A, and a second memory string 230B. The top GIDL line 201 can be coupled to gates of top GIDL transistors in the respective memory string 230 to control the top GIDL transistors. Similarly, the TSG line 205 can be coupled to gates of TSG transistors in the respective memory string 230 to control the TSG transistors (e.g., TSG transistor 108-T1 of FIG. 1C). The memory string 230 in the present disclosure may also be referred to as the string 230.

The ferroelectric memory block 200 can further include one or more bottom GIDL layers 216 and one or more BSG layers 218 between a source line 214 and the word lines 136. The bottom GIDL layers 216 can be between the source line 214 and the BSG layers 218 along Z direction. In some implementations, the ferroelectric memory block 200 includes at least one dummy BSG layer 220 between the BSG layers 218 and the word lines 136. The bottom GIDL layer 216, BSG layer 218, and dummy BSG layer 220 can have the same or different conductive materials. The bottom GIDL layer 216, BSG layer 218, and dummy BSG layer 220 can be separated from one another by dielectric layers.

In some implementations, each of the bottom GIDL layer 216 and BSG layer 218 is a continuous layer and not separated by a bottom cut structure, as illustrated in FIG. 2A and 2B. In some implementations, as illustrated in FIG. 2C, in the memory block 210, each bottom GIDL layer 216 can include a plurality of bottom GIDL lines 215 that are arranged along a lateral direction (e.g., Y direction). Adjacent bottom GIDL lines 215 can be separated by a bottom cut structure 222. Similarly, each BSG layer 218 can include a plurality of BSG lines 217 that are arranged along a lateral direction (e.g., Y direction). Adjacent BSG lines 217 can be separated by the bottom cut structure 222. In other words, the bottom cut structure 222 can extend vertically into both bottom GIDL layers 216 and BSG layers 218 to divide each bottom GIDL layer 216 into a plurality of bottom GIDL lines 215 and divide each BSG layer 218 into a plurality of BSG lines 217. In some implementations, a number of the bottom GIDL lines 215 is equal to a number of BSG lines 217. The bottom cut structure 222 can include a dielectric material, e.g., silicon oxide, silicon nitride, silicon oxynitride, or any combination thereof.

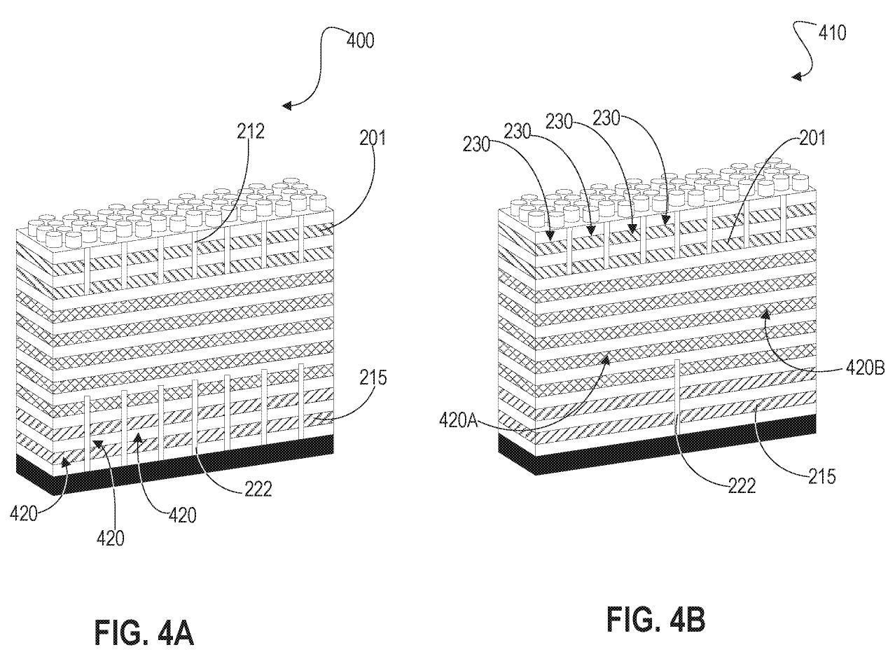

In some implementations, as illustrated in FIG. 2C, a number of the bottom cut structure 222 is smaller than a number of the top cut structures 212. As a result, a number of bottom GIDL lines 215 is smaller than a number of top GIDL lines 201. Therefore, each bottom GIDL line 215 can control two or more memory strings 230. The example implementation in FIG. 2C illustrates that each bottom GIDL line 215 can control four memory strings 230. It is to be understood that, in some implementations, a number of bottom GIDL lines 215 can be equal to a number of top GIDL lines (e.g., as shown in FIG. 4A), where each bottom GIDL line 215 can control a single memory string 230.

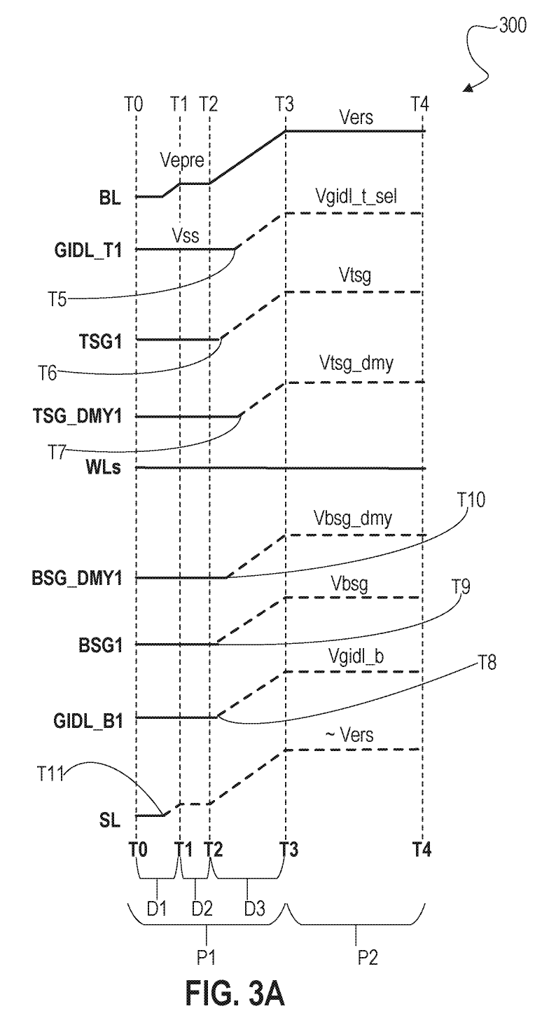

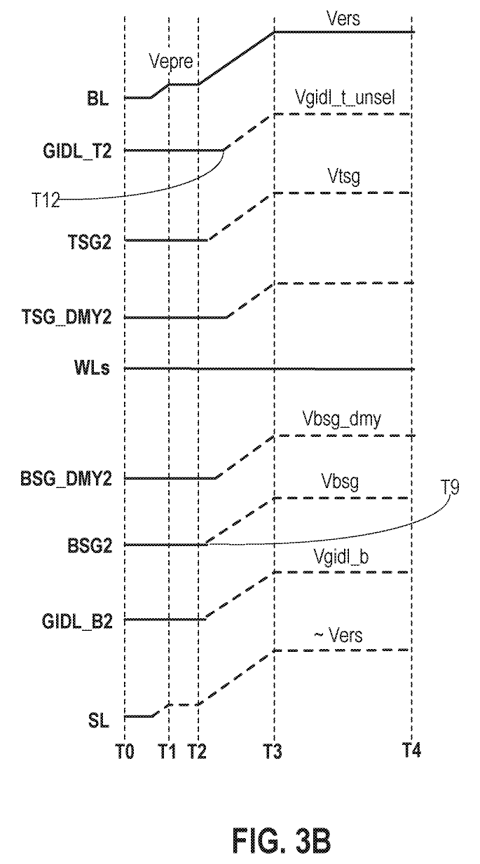

FIG. 3A illustrates an example of a voltage diagram of a first string in a top erase operation 300 of erasing the first string using a first top GIDL line. FIG. 3B illustrates an example of a voltage diagram of a second string during the top erase operation 300 of FIG. 3A. The first top GIDL line GIDL_T1 can be the top GIDL line 201 of FIGS. 2A-2C. The first string can be the first memory string 230A of FIG. 2A. The second memory string can be, e.g., the second memory string 230B of FIG. 2A. The first string and the second string can be in a same memory block (e.g., memory block 200 of FIGS. 2A and B, or memory block 210 of FIG. 2C). When the first string is selected for erase, the first string can be referred to as a selected string, and the second string can be referred to as an unselected string in the present disclosure. For simplicity, erasing a string using a top GIDL line can be referred to as the top erase operation in the present disclosure.

As illustrated in FIG. 3A, the top erase operation 300 can include a first phase P1 (e.g., from time T0 to time T3) and a second phase P2 (e.g., from time T3 to time T4). The first phase P1 can include a plurality of periods. For example, the first phase P1 can include a first period D1 from time T0 to time T1, a second period D2 from time T1 to time T2, and a third period D3 from time T2 to time T3. Time T0 can correspond to a time where all lines shown in FIG. 3A are applied with a low voltage (e.g., Vss). Time T1 can correspond to a start time of a pre-ramp voltage Vepre applied to the bit line (BL). Time T2 can correspond to an end time of the pre-ramp voltage Vepre. Time T3 can correspond to a time where a voltage of the BL is ramped to the erase voltage Vers. Time T4 can correspond to an end time of the second phase P2.

When erasing the first string using the first top GIDL line GIDL_T1, the BL can be applied with the erase voltage Vers. The first top GIDL line GIDL_T1 that corresponds to the first string can be applied with a gate-induced drain leakage (GIDL) voltage Vgidl_t_sel. In some implementations, the GIDL voltage Vgidl_t_sel is smaller than the erase voltage Vers.

In some implementations, the GIDL voltage Vgidl_t_sel is applied by a hold and release process. For example, applying the GIDL voltage Vgidl_t_sel includes applying a voltage (e.g., Vss) to the first top GIDL line GIDL_T1 between time T0 and time T5, and floating the first top GIDL line GIDL_T1 after time T5. Vss can be a ground voltage (e.g., 0 V). Time T5 can be between time T2 and time T3.

In some implementations, applying the erase voltage Vers to the BL includes: applying the pre-ramp voltage Vepre that is greater than Vss during the second period D2; ramping, during the third period D3, the voltage from the pre-ramp voltage Vepre to the erase voltage Vers; and applying, during the second phase P2, the erase voltage Vers. Therefore, during the period between time T2 and T5, the voltage of the BL is greater than Vss. Without being bound to any particular theory, this voltage difference can generate holes that can be used to erase memory cells in the first string. After time T5, as the first top GIDL line GIDL_T1 is floating, the voltage on the first top GIDL line GIDL_T1 can increase to the GIDL voltage Vgidl_t_sel due to its coupling with the BL (e.g., capacitive coupling).

During the top erase operation of the first string, a first TSG line TSG1 and a first dummy TSG line TSG_DMY1 can also be applied with a voltage using a hold and release process. For example, the first TSG line TSG1 can be applied with a voltage (e.g., Vss) between time T0 and T6, and then floating after time T6. In some implementations, time T6 is between time T2 and time T5. In other words, the first TSG line TSG1 can be held at the voltage (e.g., Vss) for a shorter duration than the first top GIDL line GIDL_T1. Similarly, in some implementations, the first dummy TSG line TSG_DMY1 can be applied with a voltage (e.g., Vss) between time T0 and T7, and then floating after time T7. In some implementations, time T7 is between time T6 and time T3. In other words, the first dummy TSG line TSG_DMY1 can be held at the voltage (e.g., Vss) for a duration longer than the first TSG line TSG1.

As the first TSG line TSG1 is adjacent to and coupled to the first top GIDL line GIDL_T1 (e.g., through capacitive coupling), the floating voltage of the first TSG line TSG1 (e.g. Vtsg) can be close to the GIDL voltage Vgidl_t_sel (e.g., differing by 10% or less, 30% or less, or 50% or less). Vtsg can be smaller than or equal to Vgidl_t_sel. As the first dummy TSG line TSG_DMY1 is adjacent to and coupled to the first TSG line TSG1 (e.g., through capacitive coupling), the floating voltage Vtsg_dmy of the first dummy TSG line TSG_DMY1 can be close to Vtsg but smaller than Vtsg. Without being bound to any particular theory, holding and releasing the first TSG line TSG1 and the first dummy TSG line TSG_DMY1 at different times may help transfer holes into the channels for erasing memory cells.

In some implementations, during the top erasing operation of the first string, the first bottom GIDL line GIDL_B1, the first BSG line BSG1, and the first dummy BSG line BSG_DMY1 can floating using a hold and release process. The source line (SL) can be capacitively coupled to the BL and can also be floating. For example, as illustrated in FIG. 3A, the SL can be held for a short period of time (e.g., from time T0 to time T11) during the first period D1, and then floating. As the SL is coupled to the BL (e.g., through capacitive coupling), the floating voltage of the SL can be close to the erase voltage Vers. In some implementations, instead of floating the SL, the SL is applied with the erase voltage Vers.

The first bottom GIDL line GIDL_B1 can be applied with a voltage (e.g., Vss) between time T0 and time T8 and then floating. The time T8 can be between time T2 and time T3. In some implementations, the time T8 is between time T2 and time T5. In other words, the first bottom GIDL line GIDL_B1 can be held for a shorter period than the first top GIDL line GIDL_T1 and floating for a longer period. In some implementations, the floating voltage Vgidl_b on the first bottom GIDL line GIDL_B1 is higher than the GIDL voltage Vgidl_t_sel. In some implementations, Vgidl_b is smaller than Vers. Without being limited to any particular theory, floating the first bottom GIDL line GIDL_B1 for a longer period can generate a higher floating voltage Vgidl_b. Therefore, a voltage difference between Vgidl_b and the floating voltage of the SL (e.g., close to Vers) can be smaller than the difference between Vgidl_t_sel and Vers. Without a sufficiently high voltage difference, holes may not be generated near the bottom GIDL transistors.

The first BSG line BSG1 and the first dummy BSG line BSG_DMY1 can be applied with a voltage (e.g., Vss) using a hold and release process in a similar manner. For example, the first BSG line BSG1 can be applied with a voltage (e.g., Vss) between time T0 and T9, and then floating after time T9. Time T9 can be between time T2 and time T3. In some implementations, the time T9 is same as the time T8. In some implementations, the time T9 is different from the time T8. Similarly, in some implementations, the first dummy BSG line BSG_DMY1 can be applied with a voltage (e.g., Vss) between time T0 and time T10, and then floating after time T10. In some implementations, time T10 is between time T8 and time T3. In other words, the first dummy BSG line BSG_DMY1 can be held at the voltage (e.g., Vss) for a duration longer than the first bottom GIDL line GIDL_B1.

As the first BSG line BSG1 is adjacent to and coupled to the first bottom GIDL line GIDL_B1 (e.g., through capacitive coupling), the floating voltage (e.g. Vbsg) of the first BSG line BSG1 can be close to Vgidl_b (e.g., differing by 10% or less, 30% or less, or 50% or less). Vbsg can be equal to or smaller than Vgidl_b. As the first dummy BSG line BSG_DMY1 is adjacent to and coupled to the first BSG line BSG1 (e.g., through capacitive coupling), the floating voltage (e.g., Vbsg_dmy) of the first dummy BSG line BSG_DMY1 can be close to Vbsg (e.g., differing by 10% or less, 30% or less, or 50% or less) but smaller than Vbsg. As used herein, the floating voltage may refer to the voltage that remains substantially stable after a ramping process. For example, the floating voltage may refer to the voltage during the second phase P2.

In some implementations, instead of floating the first bottom GIDL line GIDL_B1, the first BSG line BSG1 and the first dummy BSG line BSG_DMY1, these lines can be applied with a voltage that is greater than the GIDL voltage Vgidl_t_sel during at least the second phase P2. For example, each of applied Vbsg_dmy, Vbsg, and Vgidl_b can be greater than the GIDL voltage Vgidl_t_sel.

In some implementations, the erase voltage Vers is between 12 V and 16 V. In some implementations, the GIDL voltage Vgidl_t_sel is between 4 V and 10 V. In some implementations, the voltage Vgidl_b of the first bottom GIDL line GIDL_B1 is between 8 V and 12 V. In some implementations, the voltage Vbsg of the first BSG line BSG1 is between 8 V and 12 V. In some implementations, the voltage Vbsg_dmy of the first dummy BSG line BSG_DMY1 is between 6V and 12 V. In some implementations, the word line voltage that are applied to the word lines 136 during the top erase operation is between 0 V and 2 V.

When erasing the first string, the second top GIDL line GIDL_T2 in the second string can be floating (e.g., through a hold and release process) or applied with a voltage that is greater than the GIDL voltage Vgidl_t_sel to prevent the second string from being erased. Referring now to FIG. 3B, the second string can correspond to a second top GIDL line GIDL_T2, a second TSG line TSG2, and a second dummy TSG line TSG_DMY2. The second top GIDL line GIDL_T2 can be separated from the first top GIDL line GIDL_T1 by the top cut structure 212, as described above in reference to FIGS. 2A-2C. The second TSG line TSG2 can also be separated from the first TSG line TSG1 by the top cut structure 212. In some implementations, the first dummy TSG line TSG_DMY1 and the second dummy TSG line TSG_DMY2 are connected and may form a continuous layer. In other words, the top cut structure 212 may not extend into the dummy TSG layer (e.g., dummy TSG layer 206 of FIGS. 2A-2C). In the implementations where the first dummy TSG line TSG_DMY1 and the second dummy TSG line TSG_DMY2 are connected, they can be applied with the same voltage.

In some implementations, the second top GIDL line GIDL_T2 is floating (e.g., through a hold and release process). For example, the second top GIDL line GIDL_T2 can be applied with a voltage (e.g., Vss) between time T0 and time T12. Time T12 can be between time T2 and time T5. In other words, the second top GIDL line GIDL_T2 can be held for a duration shorter than the first top GIDL line GIDL_T1 and floating for a longer duration. In some implementations, the voltage Vgidl_t_unsel of the second top GIDL line GIDL_T2 is greater than the GIDL voltage Vgidl_t_sel. Without being limited to any particular theory, floating the second top GIDL line GIDL_T2 for a longer period can generate a higher floating voltage on the second top GIDL line GIDL_T2. Therefore, a voltage difference between Vgidl_t_unsel and Vers can be smaller than a voltage difference between Vgidl_t_sel and Vers. Without a sufficiently high voltage difference, holes may not be generated near the second top GIDL transistors. Therefore, the second string may not be erased when erasing the first string.

In some implementations, instead of holding and releasing the second top GIDL line GIDL_T2, the second top GIDL line GIDL_T2 can be applied with a voltage that is greater than Vgidl_t_sel to avoid erasing the second string. In some implementations, the voltage Vgidl_t_unsel of the second top GIDL line GIDL_T2 is between 8 V and 12 V.

In some implementations, the second TSG line TSG2 can be applied with the same hold and release process as the second top GIDL line GIDL_T2. Alternatively, the second TSG line TSG2 can be applied with a voltage that is greater than the GIDL voltage Vgidl_t_sel. In some implementations, the second dummy TSG line TSG_DMY2 can be applied with the same voltage as the first dummy TSG line TSG_DMY1, as described above.

The second string can correspond to a second bottom GIDL line GIDL_B2, a second BSG line BSG2, and a second dummy BSG line BSG_DMY2. As noted above in reference to FIGS. 2A-2C, the first and second bottom GIDL lines GIDL_B1, GIDL_B2 may be connected and form a continuous layer in the absence of a bottom cut structure 222. Similarly, the first and second BSG lines BSG1, BSG2 may be connected and form a continuous layer in the absence of the bottom cut structure 222. The first and second dummy BSG lines BSG_DMY1, BSG_DMY2 may also be connected and form a continuous layer. Therefore, the voltage applied to the second bottom GIDL line GIDL_B2 can be the same as the voltage applied to the first bottom GIDL line GIDL_B1. The voltage applied to the second BSG line BSG2 can be the same as the voltage applied to the first BSG line BSG1. The voltage applied to the second dummy BSG line BSG_DMY2 can be the same as the voltage applied to the first dummy BSG line BSG_DMY1. Hence, the second bottom GIDL line GIDL_B2, the second BSG line BSG2, and the second dummy BSG line BSG_DMY2 can be floating (e.g., through a hold and releaser process) or applied with a voltage that is greater than the GIDL voltage Vgidl_t_sel.

With the techniques described in the present disclosure, the first top GIDL line GIDL_T1 can be used to select one or more individual strings for performing a top erase operation 300. Therefore, instead of erasing the memory array at a block level, the memory array can be erased at a string level. In some implementations, two or more memory strings can be erased together by applying the GIDL voltage Vgidl_t_sel to the selected memory strings. For example, to erase the first and second strings together, the GIDL voltage Vgidl_t_sel can be applied to both the first and second top GIDL lines GIDL_T1, GIDL_T2, while the top GIDL lines in unselected memory strings can be floating or applied with a voltage greater than the GIDL voltage Vgidl_t_sel. Therefore, the top erase operation 300 can be performed on any number of selected memory strings. For example, the memory device can be configured to first erase the first string, and then erase the second string after erasing the first string. The second string can be erased using the same or similar methods as described above.

FIG. 4A illustrates an isometric view of a ferroelectric memory block 400 where a number of bottom GIDL lines 215 are equal to a number of top GIDL lines 201. FIG. 4B illustrates an isometric view of a ferroelectric memory block 410 where a number of bottom GIDL lines 215 is smaller than a number of the top GIDL lines 201. As noted above, the bottom GIDL layer 216 can be divided by one or more bottom cut structures 222 into a plurality of bottom GIDL lines 215. In the implementations where the number of bottom GIDL lines 215 is equal to the number of top GIDL lines 201, each bottom GIDL line 215 corresponds to a respective top GIDL line 201, and a bottom GIDL line 215 can be used to select a respective string. Therefore, the ferroelectric memory block 400 can be erased at an individual string level by using a bottom GIDL line 215. In the implementations where the number of bottom GIDL lines 215 is smaller than the number of the top GIDL lines 201, each bottom GIDL line 215 may correspond to two or more strings. For example, as illustrated in FIG. 4B, each bottom GIDL line 215 can correspond to four strings. Therefore, by using a bottom GIDL line 215, the ferroelectric memory block 410 can be erased at a minimum of four strings. The one or more strings that are controlled by a single bottom GIDL line 215 can be referred to as a string group or a finger in the present disclosure. Each block can include a plurality of string groups 420. Each string group 420 can include one or more strings. For example, in the example implementation shown in FIG. 4A, each string group 420 can include one string, as one bottom GIDL line 215 can control a single string. In the example implementation shown in FIG. 4B, the memory block 41 can include two string groups, e.g., a first string group 420A, and a second string group 420B. Each string group can include four strings 230, as one bottom GIDL line 215 can control four strings 230 together. It is to be noted that the example implementations shown in FIGS. 4A and 4B are not intended to be construed in a limiting sense. Any other number of string groups in a memory block and any other number of strings in a string group are also possible.

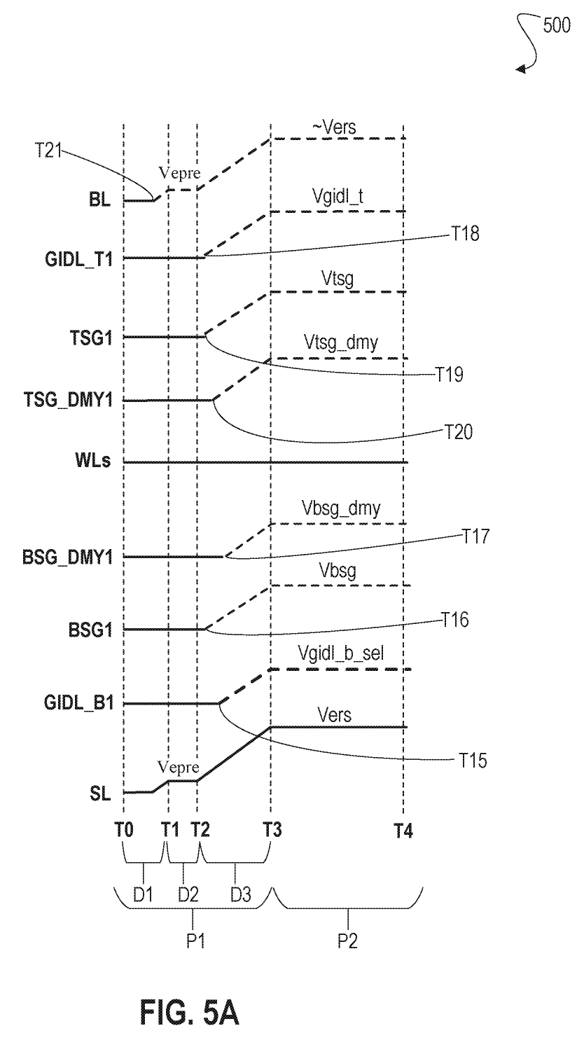

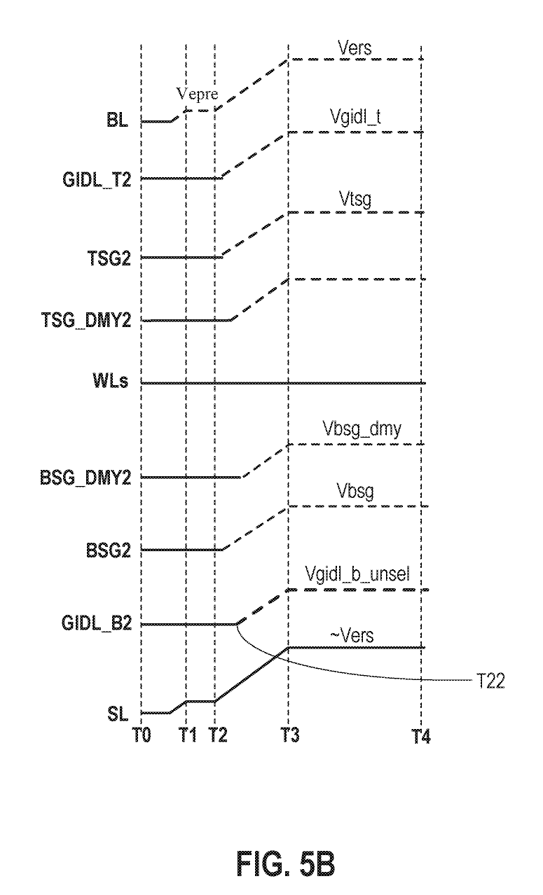

FIG. 5A illustrates an example of a voltage diagram of a first string group in a bottom erase operation 500 of erasing the first string group using a first bottom GIDL line GIDL_B1. FIG. 5B illustrates an example of a voltage diagram of a second string group in the bottom erase operation of FIG. 5A. As noted above, the bottom GIDL lines 215 can be between the SL and the word lines 136. When the first string group is selected for erase, the first string group can be referred to as a selected string group in the present disclosure, and the second string group can be referred to as an unselected string group in the present disclosure. For simplicity, erasing a string group using a bottom GIDL line can be referred to as the bottom erase operation in the present disclosure.

A method of erasing the memory cells using the bottom GIDL lines 215 can be substantially similar to the method of erasing the memory cells using the top GIDL lines 201. One of the primary differences is that a second GIDL voltage Vgidl_b_sel will be applied to the first bottom GIDL line GIDL_B1 rather than to the first top GIDL line GIDL_T1. The second GIDL voltage Vgidl_b_sel can be equal to the first GIDL voltage Vgidl_t_sel.

As illustrated in FIG. 5A, the bottom erase operation 500 can include a first phase P1 P1 (e.g., from time T0 to time T3) and a second phase P2 (e.g., from time T3 to time T4). The first phase P1 can include a plurality of periods. For example, the first phase P1 can include a first period D1 from time T0 to time T1, a second period D2 from time T1 to time T2, and a third period D3 from time T2 to time T3. When erasing the first string group using the first bottom GIDL line GIDL_B1, the SL can be applied with an erase voltage Vers. The first bottom GIDL line GIDL_B1 that corresponds to the first string group can be applied with the second GIDL voltage Vgidl_b_sel. In some implementations, the second GIDL voltage Vgidl_b_sel is smaller than the erase voltage Vers.

In some implementations, the second GIDL voltage Vgidl_b_sel is applied to the first bottom GIDL line GIDL_B1 by a hold and release process. For example, applying the second GIDL voltage Vgidl_b_sel includes applying a voltage (e.g., Vss) to the first bottom GIDL line GIDL_B1 between time T0 and time T15; and floating the first bottom GIDL line GIDL_B1 after time T15. In some implementations, time T15 is same as time T5.

In some implementations, applying the erase voltage Vers to the SL includes: applying a pre-ramp voltage Vepre that is greater than Vss during the second period D2; ramping, during the third period D3, from the pre-ramp voltage Vepre to the erase voltage Vers; and applying, during the second phase P2, the erase voltage Vers. Therefore, during the period between time T2 and time T15, the voltage of the SL is greater than Vss. Without being bound to any particular theory, this voltage difference can generate holes that can be used to erase memory cells in the first string group. After time T15, as the first bottom GIDL line GIDL_B1 is floating, the voltage on the first bottom GIDL line GIDL_B1 can increase to the second GIDL voltage Vgidl_b_sel due to its coupling with the SL. Vgidl_b_sel can be smaller than Vers.

During the bottom erase operation of the first string group, a first BSG line BSG1 and a first dummy BSG line BSG_DMY1 can also be applied with a voltage using a hold and release process. For example, the first BSG line BSG1 can be applied with a voltage (e.g., Vss) between time T0 and time T16, and then floating after time T16. In some implementations, time T16 is same as T6. In some implementations, time T16 is between time T2 and time T15. In other words, the first BSG line BSG1 can be held at the voltage (e.g., Vss) for a shorter duration than the first bottom GIDL line GIDL_B1. Similarly, in some implementations, the first dummy BSG line BSG_DMY1 can be applied with a voltage (e.g., Vss) between time T0 and time T17, and then floating after time T17. In some implementations, time T17 is same as T7. In some implementations, time T17 is between time T16 and time T3. In other words, the first dummy BSG line BSG_DMY1 can be held at the voltage (e.g., Vss) for a duration longer than the first BSG line BSG1. As the first BSG line BSG1 is adjacent to and coupled to the first bottom GIDL line GIDL_B1 (e.g., through capacitive coupling), the floating voltage of the first BSG line BSG1 (e.g. Vbsg) can be close to the second GIDL voltage Vgidl_b_sel (e.g., differing by 10% or less, 30% or less, or 50% or less). In some implementations, Vbsg is equal to or smaller than the second GIDL voltage Vgidl_b_sel. As the first dummy BSG line BSG_DMY1 is adjacent to and coupled to the first BSG line BSG1 (e.g., through capacitive coupling), the floating voltage of the first dummy BSG line BSG_DMY1 can be close to the BSG voltage Vbsg but smaller than the BSG voltage Vbsg. Without being bound to any particular theory, holding and releasing the first BSG line BSG1 and first dummy BSG line BSG_DMY1 at different times may help transfer holes into the channels for erasing memory cells.

In some implementations, during the bottom erasing operation of the first string group using the first bottom GIDL line GIDL_B1, the first top GIDL line GIDL_T1, the first TSG line TSG1, and the first dummy TSG line TSG_DMY1 can be floating using a hold and release process. The BL can be capacitively coupled to the SL and can also be floating. For example, as illustrated in FIG. 5A, the BL can be held for a short period of time (e.g., from time T0 to time T21) during the first period D1, and then floating. Time T21 can be the same as time T11. As the BL is coupled to the SL (e.g., through capacitive coupling), the floating voltage of the BL can be close to the erase voltage Vers (e.g., differing by 10% or less, 30% or less, or 50% or less). In some other implementations, instead of floating the BL, the BL is applied with the erase voltage Vers.

The first top GIDL line GIDL_T1 can be applied with a voltage (e.g., Vss) between time T0 and time T18 and then floating. Time T18 can be the same as T8. Time T18 can be between time T2 and time T3. In some implementations, the time T18 is between time T2 and time T15. In other words, the first top GIDL line GIDL_T1 is held for a shorter period than the first bottom GIDL line GIDL_B1, and floating for a longer period. In some implementations, the floating voltage Vgidl_t of the first top GIDL line GIDL_T1 is higher than the second GIDL voltage Vgidl_b_sel. In some implementations, Vgidl_t is smaller than Vers. Without being limited to any particular theory, floating the first top GIDL line GIDL_T1 for a longer period can generate a higher floating voltage Vgidl_t. Therefore, a voltage difference between Vgidl_t and the floating voltage of the BL (e.g., close to Vers) can be smaller than the difference between Vgidl_b_sel and Vers. Without a sufficiently high voltage difference, holes may not be generated near the first top GIDL transistors.

The first TSG line TSG1 and the first dummy line TSG TSG_DMY1 can be applied with a voltage using a hold and release process in a similar manner. For example, the first TSG line TSG1 can be applied with a voltage (e.g., Vss) between time T0 and time T19, and then floating after time T19. Time T19 can be the same as T9. Time T19 is between time T2 and time T3. In some implementations, time T19 is the same as the time T18. In some implementations, the time T19 is different from the time T18.

Similarly, in some implementations, the first dummy TSG line TSG_DMY1 can be applied with a voltage between time T0 and time T20, and then floating after time T20. In some implementations, time T20 is between time T18 and time T3. In other words, the first dummy TSG line TSG_DMY1 can be held at the voltage (e.g., Vss) for a duration longer than the first top GIDL line GIDL_T1.

As the first TSG line TSG1 is adjacent to and coupled to the first top GIDL line GIDL_T1 (e.g., through capacitive coupling), the floating voltage (e.g., Vtsg) of the first TSG line TSG1 can be close to Vgidl_t (e.g., differing by 10% or less, 30% or less, or 50% or less). Vtsg can be equal to or smaller than Vgidl_t. As the first dummy TSG line TSG_DMY1 is adjacent to and coupled to the first TSG line TSG1 (e.g., through capacitive coupling), the floating voltage (e.g., Vtsg_dmy) of the first dummy TSG line TSG_DMY1 can be close to Vtsg (e.g., differing by 10% or less, 30% or less, or 50% or less) but smaller than Vtsg. As used herein, the floating voltage may refer to the voltage that remains substantially stable after a ramping process. For example, the floating voltage may refer to the voltage during the second phase P2.

In some implementations, instead of floating the first top GIDL line GIDL_T1, the first TSG line TSG1 and the first dummy TSG line TSG_DMY1, these lines can be applied with a voltage that is greater than the second GIDL voltage Vgidl_b_sel during at least the second phase P2. For example, each of applied voltages (e.g., Vtsg_dmy, Vtsg, and Vgidl_t) can be greater than the second GIDL voltage Vgidl_b_sel.

In some implementations, the erase voltage Vers is between 12 V and 16 V. In some implementations, the second GIDL voltage Vgidl_b_sel is between 4 V and 10 V. In some implementations, the voltage of the first top GIDL line GIDL_T1 is between 8 V and 12 V. In some implementations, the voltage of the first TSG line TSG1 is between 8 V and 12 V. In some implementations, the voltage of the first dummy TSG line TSG_DMY1 is between 6V and 12 V. In some implementations, the word line voltage that are applied to the word lines 136 during the bottom erase operation is between 0 V and 2 V.

When erasing the first string group, the first bottom GIDL line GIDL_B1 in the second string group (e.g. unselected string group) can be floating (e.g., through a hold and release process) or applied with a voltage that is greater than the second GIDL voltage Vgidl_b_sel to prevent the second string group from being erased. Referring now to FIG. 5B, the second string group can correspond to a second bottom GIDL line GIDL_B2, a second BSG line BSG2, and a BSG2second dummy BSG line BSG_DMY2. The second bottom GIDL line GIDL_B2 is separated from the first bottom GIDL line GIDL_B1 by the bottom cut structure 222, as described above in reference to FIGS. 2A-2C and 4A-4B. The second BSG line BSG2 is separated from the first BSG line BSG1 by the bottom cut structure 222. In some implementations, the first dummy BSG line BSG_DMY1 and the second dummy BSG line BSG_DMY2 are connected and may form a continuous layer. In other words, the bottom cut structure 222 may not extend into the first dummy BSG line BSG_DMY1 layer. In the implementations where the first dummy BSG line BSG_DMY1 and the second dummy BSG line BSG_DMY2 are connected, the second dummy BSG line BSG_DMY2 can be applied with the same voltages as the first dummy BSG line BSG_DMY1.

In some implementations, the second bottom GIDL line GIDL_B2 is floating (e.g., through a hold and release process). For example, the second bottom GIDL line GIDL_B2 can be applied with a voltage (e.g., Vss) between time T0 and time T22. Time T22 can be the same as time T12. Time T22 can be between time T2 and time T15. In other words, the second bottom GIDL line GIDL_B2 can be held for a duration shorter than the first bottom GIDL line GIDL_B1 and floating for a longer duration. In some implementations, the voltage Vgidl_b_unsel of the second bottom GIDL line GIDL_B2 is higher than Vgidl_b_sel . Without being limited to any particular theory, floating the second bottom GIDL line GIDL_B2 for a longer period can generate a higher floating voltage Vgidl_b_unsel on the second bottom GIDL line GIDL_B2. Therefore, a voltage difference between Vgidl_b_unsel and the erase voltage Vers can be smaller than the difference between Vgidl_b_sel and Vers. Without a sufficiently high voltage difference, holes may not be generated near the second bottom GIDL transistors in unselected string groups. Therefore, the second string group may not be erased when erasing the first string group.

In some implementations, instead of holding and releasing the second bottom GIDL line GIDL_B2, the second bottom GIDL line GIDL_B2 can be applied with a voltage Vgidl_b_unsel that is greater than the second GIDL voltage Vgidl_b_sel to prevent erasing the second string group.

In some implementations, the second BSG line BSG2 can be applied with the same hold and release process as the second bottom GIDL line GIDL_B2. Alternatively, the second BSG line BSG2 can be applied with a voltage that is greater than the second GIDL voltage Vgidl_b_sel. In some implementations, the second dummy BSG line BSG_DMY2 can be applied with the same voltage as the first dummy BSG line BSG_DMY1, as described above.

The second string group can correspond to a second top GIDL line GIDL_T2, a second TSG line TSG2, and a second dummy TSG line TSG_DMY2. The second top GIDL line GIDL_T2, the second TSG line TSG2, and the second dummy TSG line TSG_DMY2 can be floating or applied with a voltage that is greater than the second GIDL voltage Vgidl_b_sel. In the bottom erase operation, the second top GIDL line GIDL_T2, the second TSG line TSG2, and the second dummy TSG line TSG_DMY2 can be floating using hold and release processes that are same as or similar to those of the first top GIDL line GIDL_T1, the first TSG line TSG1, and the first dummy TSG line TSG_DMY1, respectively, as described above in reference to FIG. 5A.

With the techniques described in the present disclosure, the first bottom GIDL line GIDL_B1 can be used to select individual string groups for performing an erase operation. Therefore, instead of erasing the memory array at a block level (e.g., a block including a plurality of memory string groups), the memory array can be erased at a string group level. A block can include a plurality of string groups. In some implementations, two or more memory string groups can be erased together by applying the second GIDL voltage Vgidl_b_sel to those memory string groups. For example, to erase the first and second string groups together, the second GIDL voltage Vgidl_b_sel (e.g., through a hold and release process) can be applied to both the first and second bottom GIDL lines GIDL_B1, GIDL_B2, while the bottom GIDL lines 215 in unselected memory string groups can be floating or applied with a voltage greater than the second GIDL voltage Vgidl_b_sel. Therefore, the erase operation can be performed on any number of selected memory string groups.

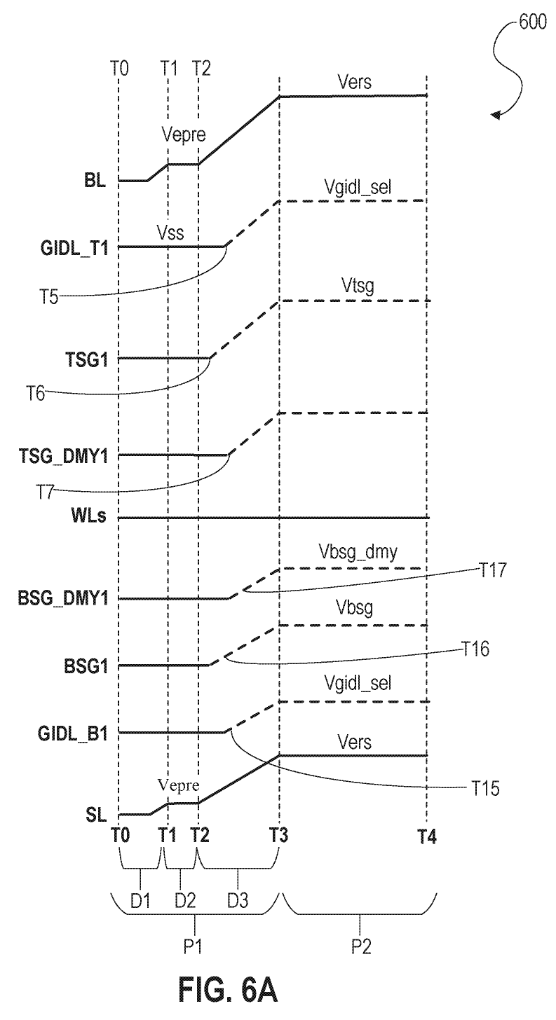

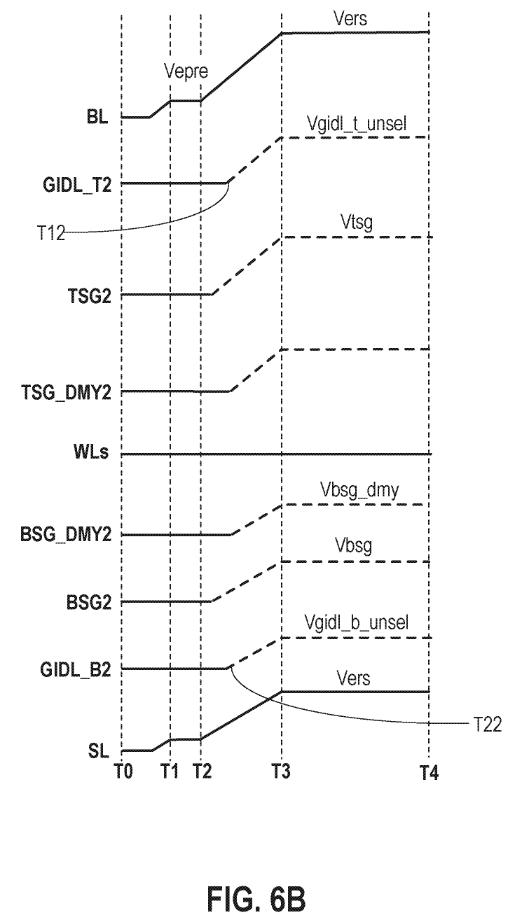

FIG. 6A illustrates an example of a voltage diagram of a first string group in a top and bottom erase operation for erasing the first string group using both a first top GIDL line GIDL_T1 and a first bottom GIDL line GIDL_B1. FIG. 6B illustrates an example of a voltage diagram of a second string group in the top and bottom erase operation of FIG. 6A. When using both the first top and bottom GIDL lines during an erase operation, the minimum erase size may be a string group that is controlled by a bottom GIDL line. In other words, the minimum number of strings that can be erased at one erase operation when using both the first top GIDL line GIDL_T1 and the first bottom GIDL line GIDL_B1 may be limited by the number of strings in a string group. For example, in the example implementation shown in FIG. 4A, the minimum number of strings that can be erased using both top and bottom GIDL lines 201, 215 is one string, while in the example implementation shown in FIG. 4B, the minimum number of the strings that can be erased using both top and bottom GIDL lines 201, 215 is four strings.

As illustrated in FIG. 6A, the top and bottom erase operation 600 (e.g., erasing the first string group from the first top and bottom GIDL lines) can be a combination of the top erase operation 300 described in reference to FIGS. 3A and 3B and the bottom erase operation 500 described in reference to FIGS. 5A and 5B. For example, as illustrated in FIG. 6A, both the SL and the BL can be applied with the erase voltage Vers, and both first top and bottom GIDL lines GIDL_T1, GIDL_B1 are applied with a GIDL voltage Vgidl_sel. The GIDL voltage Vgidl_sel can be the same as the first GIDL voltage Vgidl_t_sel and/or the second GIDL voltage Vgidl_b_sel. Therefore, without being bound to any particular theory, holes can be generated near both top and bottom GIDL transistors, and these holes can be migrated into channels for erasing memory cells.

The first TSG line TSG1 and the first dummy TSG line TSG_DMY1 can be operated in a same manner as in the top erase operation 300 described in reference to FIG. 3A. The first BSG line BSG1 and the first dummy BSG line BSG_DMY1 can be operated in a same manner as in the bottom erase operation 500 described in reference to FIG. 5A. For the unselected strings (e.g., the second string), various lines (e.g., GIDL lines, TSG lines, BSG lines) in the unselected strings can be operated in the same manner as those described in reference to FIGS. 3B and 5B. For brevity, redundant descriptions are omitted here.

It is to be noted that although a same voltage label may be used across FIGS. 3A-3B, 5A-5B and 6A-6B, the voltage value may be the same or different. For example, the first TSG line TSG1 is shown in FIGS. 3A-3B, 5A-5B and 6A-6B to have a voltage Vtsg. Vtsg in these figures may have same or different values. Additionally, Vtsg can be a floating voltage or an applied voltage to the first TSG line TSG1. Other voltage labels can be construed in a similar manner.

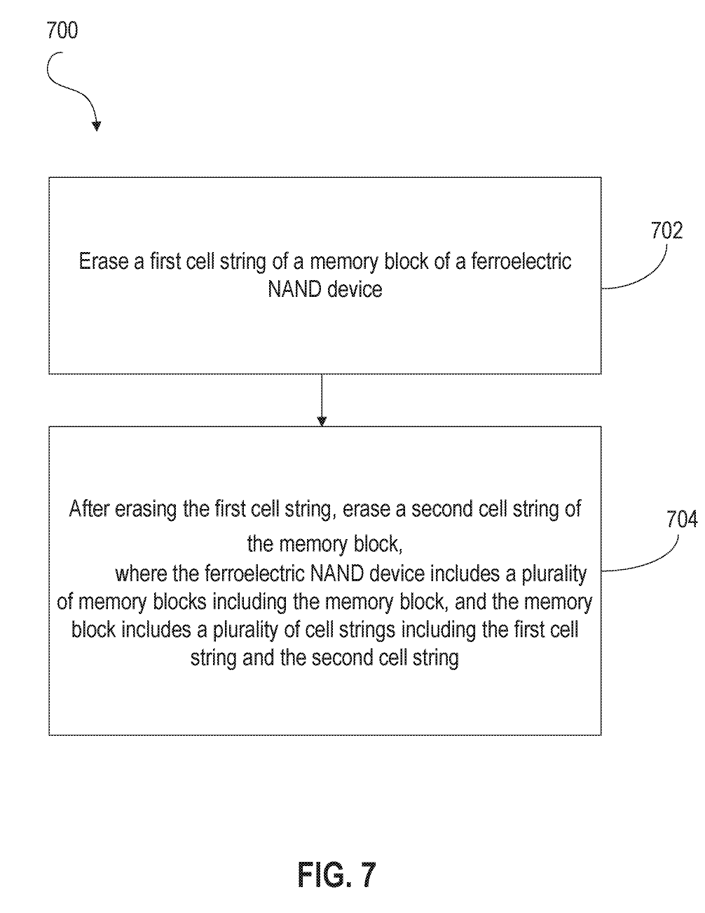

FIG. 7 illustrates a flowchart of an example of a method 700 of erasing a ferroelectric NAND device. The ferroelectric NAND device can be, e.g., the 3D semiconductor device 100 of FIG. 1D.

At step 702, a first cell string of a memory block of the ferroelectric NAND device is erased. The first cell string can be, e.g., the first memory string 230A of FIG. 2A. The memory block can be, e.g., the memory block 200 of FIGS. 2A and 2B, the memory block 210 of FIG. 2C, the memory block 400 of FIG. 4A, or the memory block 410 of FIG. 4B.

At step 704, after erasing the first cell string, a second cell string of the memory block is erased. The ferroelectric NAND device includes a plurality of memory blocks including the memory block, and the memory block includes a plurality of cell strings including the first cell string and the second cell string. The second cell string can be, e.g., the second memory string 230B of FIG. 2A.

In some implementations, erasing the first cell string of the memory block includes applying a gate-induced drain leakage (GIDL) voltage to a first GIDL line corresponding to the first cell string, and erasing the second cell string of the memory block includes applying the GIDL voltage to a second GIDL line corresponding to the second cell string, as described above in reference to FIGS. 3A-6B. The first GIDL line can be, e.g., the first top GIDL line GIDL_T1 of FIGS. 3A-3B, 5A-5B and 6A-6B, a top GIDL line 201 of FIGS. 2A-2B and 4A-4B, the first bottom GIDL line GIDL_B1 of FIGS. 3A-3B, 5A-5B and 6A-6B, or a bottom GIDL line 215 of FIGS. 2A-2B and 4A-4B. The second GIDL line can be, e.g., the second top GIDL line GIDL_T2 of FIGS. 3A-3B, 5A-5B and 6A-6B, a top GIDL line 201 of FIGS. 2A-2B and 4A-4B, the second bottom GIDL line GIDL_B1 of FIGS. 3A-3B, 5A-5B and 6A-6B, or a bottom GIDL line 215 of FIGS. 2A-2B and 4A-4B. The GIDL voltage can be, e.g., Vgidl_t_sel of FIG. 3A, Vgidl_b_sel of FIG. 5A, or Vgidl_sel of FIG. 6A.

In some implementations, erasing the first cell string includes: applying a first voltage to the second GIDL line, the first voltage being greater than the GIDL voltage; or applying, during a first phase, a second voltage to the second GIDL line, and floating, during a second phase after the first phase, the second GIDL line. The first voltage can be, e.g., Vgidl_t_unsel of FIGS. 3B and 6B, or Vgidl_b_unsel of FIGS. 5B and 6B. The first phase can be, e.g., the duration between time T0 and time T12 of FIGS. 3B and 6B, or the duration between time T0 and time T22 of FIGS. 5B and 6B. The second phase can be, e.g., the duration between time T12 and time T4 of FIGS. 3B and 6B, or the duration between time T22 and time T4 of FIGS. 5B and 6B.

In some implementations, applying the GIDL voltage to the first GIDL line includes: applying, during a third phase, a third voltage to the first GIDL line; and floating, during a fourth phase after the third phase, the first GIDL line. The third phase can be, e.g., the duration between time T0 and time T5 of FIGS. 3A and 6A, or the duration between time T0 and time T15 of FIGS. 5A and 6A. The fourth phase can be, e.g., the duration between time T5 and time T4 of FIGS. 3A and 6A, or the duration between time T15 and time T4 of FIGS. 5A and 6A.

In some implementations, the first GIDL line is between a bit line and word lines, and erasing the first cell string includes: applying an erase voltage to the bit line, the erase voltage being greater than the GIDL voltage; and performing one of: applying a fourth voltage to a third GIDL line that is between the word lines and a source line, the third GIDL line corresponding to the first cell string; or applying, during a fifth phase, a fifth voltage to the third GIDL line, and floating, during a sixth phase after the fifth phase, the third GIDL line to generate a floating voltage on the third GIDL line. The bit line can be, e.g., the bit line 112 of FIGS. 1B and 1E, or the BL of FIGS. 3A-3B, 5A-5B and 6A-6B. The word lines can be, e.g., the word lines 136 of FIGS. 1B and 1E, or the WLs of FIGS. 3A-3B, 5A-5B and 6A-6B. The erase voltage can be, e.g., Vers of FIGS. 3A-3B, 5A-5B and 6A-6B. The first GIDL line can be, e.g., the first top GIDL line GIDL_T1 of FIG. 3A. The GIDL voltage can be, e.g., Vgidl_t_sel of FIG. 3A. The fourth voltage can be, e.g., Vgidl_b of FIG. 3A. The third GIDL line can be, e.g., the first bottom GIDL line GIDL_B1 of FIG. 3A. The fifth phase can be, e.g., the duration between time T0 and time T8 of FIG. 3A. The fifth voltage can be, e.g., Vss. The sixth phase can be, e.g., the duration between T8 and T4 of FIG. 3A. The floating voltage can be, e.g., Vgidl_b of FIG. 3A.

In some implementations, the third phase overlaps with the fifth phase, and the third phase is longer than the fifth phase. For example, time T5 is between time T8 and time T4.

In some implementations, at least one of the fourth voltage or the floating voltage of the third GIDL line is greater than the GIDL voltage. For example, Vgidl_b is greater than Vgidl_t_sel in FIG. 3A.

In some implementations, erasing the first cell string includes: applying, during a seventh phase, a bottom select gate (BSG) voltage to a first BSG line that corresponds to the first cell string and a second BSG line that corresponds to the second cell string; and floating, during an eighth phase after the seventh, the first BSG line and the second BSG line. The seventh phase can be, e.g., the duration between time T0 and time T9 of FIGS. 3A and 3B. The first BSG line can be, e.g., the first BSG line BSG1 of FIGS. 3A, 5A, and 6A. The second BSG line can be, e.g., the second BSG line BSG2 of FIGS. 3B, 5B, and 6B. The BSG voltage can be, e.g., Vbsg of FIGS. 3A and 3B. The eighth phase can be, e.g., the duration between T9 and T4 of FIGS. 3A and 3B.

In some implementations, erasing the first cell string includes: applying, during a ninth phase, a third BSG line that is between the word lines and the first BSG line, the third BSG line corresponding to the first cell string; and floating, during a tenth phase after the ninth phase, the third BSG line, where a voltage of the third BSG line is smaller than a voltage of the first BSG line, the voltage of the first BSG line is smaller than a voltage of the third GIDL line, and the voltage of the third GIDL line is smaller than the erase voltage, and where the voltage of the third GIDL includes one of the fourth voltage or the floating voltage. The third BSG line can be, e.g., the first dummy BSG line BSG_DMY1 of FIG. 3A. The ninth phase can be, e.g., the duration between time T0 and time T10 of FIG. 3A. The tenth phase can be, e.g., the duration between time T10 and time T4 of FIG. 3A. The voltage of the third BSG line can be, e.g., Vbsg_dmy of FIG. 3A. The voltage of the first BSG line can be, e.g., Vbsg of FIG. 3A. The voltage of the third GIDL line can be, e.g., Vgidl_b of FIG. 3A.

In some implementations, the first GIDL line is between word lines and a source line, and where erasing the first cell string includes: applying an erase voltage to the source line, the erase voltage being greater than the GIDL voltage; and performing one of: applying a first voltage to a third GIDL line that is between the word lines and a bit line, the third GIDL line corresponding to the first cell string; or applying, during a first phase, a second voltage to the third GIDL line, and floating, during a second phase after the first phase, the third GIDL line to generate a floating voltage on the third GIDL line. The source line can be, e.g., the SL of FIGS. 3A-3B, 5A-5B and 6A-6B. The first GIDL line here can be, e.g., the first bottom GIDL line GIDL_B1 of FIG. 5A. The erase voltage can be, e.g., Vers of FIG. 5A. The GIDL voltage can be, e.g., Vgidl_b_sel of FIG. 5A. The first voltage can be, e.g., Vgidl_t of FIG. 5A. The third GIDL line can be, e.g., the first top GIDL line GIDL_T1 of FIG. 5A. The first phase can be, e.g., the duration between time T0 and time T18 of FIG. 5A. The second voltage can be, e.g., Vss. The second phase can be, e.g., the duration between time T18 and time T4 of FIG. 5A. The floating voltage on the third GIDL line can be, e.g., Vgidl_t of FIG. 5A.

In some implementations, at least one of the first voltage or the floating voltage of the third GIDL line is greater than the GIDL voltage.

In some implementations, the first GIDL line is isolated from the second GIDL line, as described in reference to FIGS. 2A-2B and 4A-4B.

In some implementations, erasing the first cell string includes: applying an erase voltage to a bit line and a source line, the erase voltage being greater than the GIDL voltage; and applying the GIDL voltage to a third GIDL line corresponding to the first cell string, the first GIDL line and the third GIDL line being on opposite sides of word lines, respectively. The GIDL voltage can be, e.g., Vgidl_sel of FIG. 6A. The first GIDL line can be, e.g., the first top GIDL line GIDL_T1 of FIG. 6A. The third GIDL line can be, e.g., the first bottom GIDL line GIDL_B1 of FIG. 6A.

In some implementations, the method includes erasing a plurality of first cell strings of the memory block by applying the GIDL voltage to at least one first GIDL line corresponding to the plurality of first cell strings, the plurality of first cell strings including the first cell string, the at least one first GIDL line including the first GIDL line; and after erasing the plurality of first cell strings, erasing a plurality of second cell strings of the memory block by applying the GIDL voltage to at least one second GIDL line, the plurality of second cell strings including the second cell string, the at least one second GIDL line including the second GIDL line, where the at least one first GIDL line is isolated from the at least one second GIDL line, as described above in reference to FIGS. 2A-6B.

In some implementations, the method includes applying a word line voltage to a word line, the word line voltage being smaller than the GIDL voltage; and applying an erase voltage to at least one of a bit line or a source line, the erase voltage being greater than the GIDL voltage, as described above in reference to FIGS. 2A-6B.

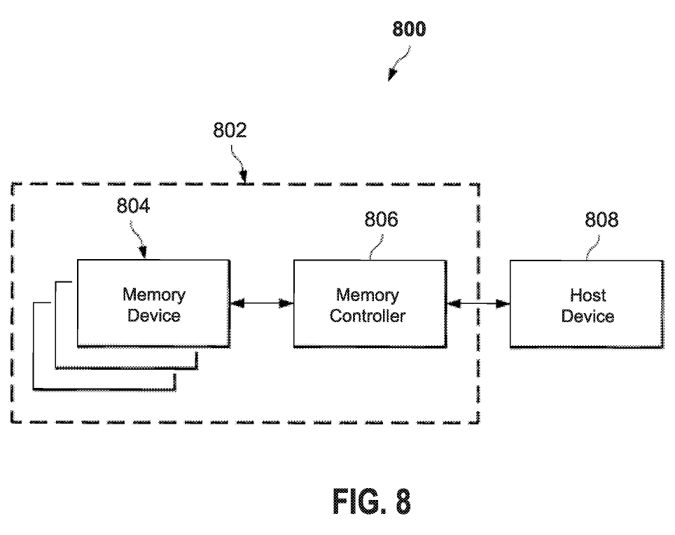

FIG. 8 illustrates a block diagram of a system 800 having one or more semiconductor devices (e.g., memory devices), according to one or more implementations of the present disclosure. The system 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, the system 800 can include a host device 808 and a memory system 802 having one or more 3D memory devices 804 and a memory controller 806. Host device 808 can include a processor of an electronic device, such as a central processing unit (CPU), or a system-on-chip (SoC), such as an application processor (AP). Host device 808 can be configured to send or receive data to or from the one or more 3D memory devices 804.

A 3D memory device 804 can be any 3D memory device disclosed herein, such as the 3D semiconductor device 100 of FIG. 1D, or a part of the 3D semiconductor device 100 (e.g., the memory block 200 of FIGS. 2A and 2B, the memory block 210 of FIG. 2C, the memory block 400 of FIG. 4A, or the memory block 410 of FIG. 4B).

In some implementations, a 3D memory device 804 includes a NAND Flash memory. Memory controller 806 (a.k.a., a controller circuit) is coupled to 3D memory device 804 and host device 808. Consistent with implementations of the present disclosure, 3D memory device 804 can include a plurality of conductive interconnections through a cover layer that are in contact with conductive pads in a conductive pad layer, and memory controller 806 can be coupled to 3D memory device 804 through at least one of the plurality of conductive interconnections. Memory controller 806 is configured to control 3D memory device 804. For example, memory controller 806 may be configured to operate a plurality of channel structures via word lines. Memory controller 806 can manage data stored in 3D memory device 804 and communicate with host device 808.

In some implementations, memory controller 806 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program (or write) operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804.

Memory controller 806 can communicate with an external device (e.g., host device 808) according to a particular communication protocol. For example, memory controller 806 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 8, memory controller 806 and a single 3D memory device 804 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory block, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature’s relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “bottom” surface and a “bottom” surface. The bottom surface of the substrate is typically where a semiconductor device is formed, and therefore the semiconductor device is formed at a bottom side of the substrate unless stated otherwise. The bottom surface is opposite to the bottom surface and therefore a bottom side of the substrate is opposite to the bottom side of the substrate. The substrate itself can be patterned. Materials added on bottom of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non- conductive material, such as a glass, a plastic, or a sapphire wafer.

As used herein, the term “layer” refers to a material portion including a region with a thickness. A layer has a bottom side and a bottom side where the bottom side of the layer is relatively close to the substrate and the bottom side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a bottom surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+-.10%, .+-.20%, or .+-.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented string groups of memory cell transistors (referred to herein as “memory string groups,” such as NAND string groups) on a laterally-oriented substrate so that the memory string groups extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method of erasing a ferroelectric NAND device, the method comprising:
erasing a first cell string of a memory block of the ferroelectric NAND device; and
after erasing the first cell string, erasing a second cell string of the memory block,
wherein the ferroelectric NAND device comprises a plurality of memory blocks including the memory block, and the memory block comprises a plurality of cell strings including the first cell string and the second cell string.

2. The method of claim 1,
wherein erasing the first cell string of the memory block comprises applying a gate-induced drain leakage (GIDL) voltage to a first GIDL line corresponding to the first cell string, and
wherein erasing the second cell string of the memory block comprises applying the GIDL voltage to a second GIDL line corresponding to the second cell string.

3. The method of claim 2, wherein erasing the first cell string comprises:
applying a first voltage to the second GIDL line, the first voltage being greater than the GIDL voltage; or
applying, during a first phase, a second voltage to the second GIDL line, and floating, during a second phase after the first phase, the second GIDL line.

4. The method of claim 2, wherein applying the GIDL voltage to the first GIDL line comprises:
applying, during a third phase, a third voltage to the first GIDL line; and
floating, during a fourth phase after the third phase, the first GIDL line.

5. The method of claim 4, wherein the first GIDL line is between a bit line and word lines, and
wherein erasing the first cell string comprises:
applying an erase voltage to the bit line, the erase voltage being greater than the GIDL voltage; and
performing one of:
applying a fourth voltage to a third GIDL line that is between the word lines and a source line, the third GIDL line corresponding to the first cell string; or
applying, during a fifth phase, a fifth voltage to the third GIDL line, and floating, during a sixth phase after the fifth phase, the third GIDL line to generate a floating voltage on the third GIDL line.

6. The method of claim 5, wherein the third phase overlaps with the fifth phase, and the third phase is longer than the fifth phase.

7. The method of claim 5, wherein at least one of the fourth voltage or the floating voltage of the third GIDL line is greater than the GIDL voltage.

8. The method of claim 7, wherein erasing the first cell string comprises:
applying, during a seventh phase, a bottom select gate (BSG) voltage to a first BSG line that corresponds to the first cell string and a second BSG line that corresponds to the second cell string; and
floating, during an eighth phase after the seventh, the first BSG line and the second BSG line.

9. The method of claim 8, wherein erasing the first cell string comprises:
applying, during a ninth phase, a third BSG line that is between the word lines and the first BSG line, the third BSG line corresponding to the first cell string; and
floating, during a tenth phase after the ninth phase, the third BSG line,
wherein a voltage of the third BSG line is smaller than a voltage of the first BSG line, the voltage of the first BSG line is smaller than a voltage of the third GIDL line, and the voltage of the third GIDL line is smaller than the erase voltage, and wherein the voltage of the third GIDL comprises one of the fourth voltage or the floating voltage.

10. The method of claim 2, wherein the first GIDL line is between word lines and a source line, and
wherein erasing the first cell string comprises:
applying an erase voltage to the source line, the erase voltage being greater than the GIDL voltage; and
performing one of:
applying a first voltage to a third GIDL line that is between the word lines and a bit line, the third GIDL line corresponding to the first cell string; or
applying, during a first phase, a second voltage to the third GIDL line, and floating, during a second phase after the first phase, the third GIDL line to generate a floating voltage on the third GIDL line.

11. The method of claim 10, wherein at least one of the first voltage or the floating voltage of the third GIDL line is greater than the GIDL voltage.

12. The method of claim 2, wherein erasing the first cell string comprises:
applying an erase voltage to a bit line and a source line, the erase voltage being greater than the GIDL voltage; and
applying the GIDL voltage to a third GIDL line corresponding to the first cell string, the first GIDL line and the third GIDL line being on opposite sides of word lines, respectively.

13. The method of claim 2, comprising:
erasing a plurality of first cell strings of the memory block by applying the GIDL voltage to at least one first GIDL line corresponding to the plurality of first cell strings, the plurality of first cell strings comprising the first cell string, the at least one first GIDL line comprising the first GIDL line; and
after erasing the plurality of first cell strings, erasing a plurality of second cell strings of the memory block by applying the GIDL voltage to at least one second GIDL line, the plurality of second cell strings comprising the second cell string, the at least one second GIDL line comprising the second GIDL line,
wherein the at least one first GIDL line is isolated from the at least one second GIDL line.

14. The method of claim 2, comprising:
applying a word line voltage to a word line, the word line voltage being smaller than the GIDL voltage; and
applying an erase voltage to at least one of a bit line or a source line, the erase voltage being greater than the GIDL voltage.

15. A ferroelectric NAND device, comprising:
a plurality of memory blocks, a memory block of the plurality of memory blocks comprising a plurality of cell strings including a first cell string and a second cell string; and
a peripheral circuit coupled to the memory block of the plurality of memory blocks, wherein the peripheral circuit is configured to perform an erase operation by:
erasing the first cell string; and
after erasing the first cell string, erasing the second cell string.

16. The ferroelectric NAND device of claim 15,
wherein for erasing the first cell string of the memory block, the peripheral circuit is configured to apply a gate-induced drain leakage (GIDL) voltage to a first GIDL line corresponding to the first cell string, and
wherein for erasing the second cell string of the memory block, the peripheral circuit is configured to apply the GIDL voltage to a second GIDL line corresponding to the second cell string.

17. The ferroelectric NAND device of claim 16, wherein for erasing the first cell string, the peripheral circuit is configured to:
apply a first voltage to the second GIDL line, the first voltage being greater than the GIDL voltage; or
apply, during a first phase, a second voltage to the second GIDL line, and floating, during a second phase after the first phase, the second GIDL line.

18. The ferroelectric NAND device of claim 16, wherein the first GIDL line is between a bit line and word lines,
wherein for erasing the first cell string, the peripheral circuit is configured to:
apply an erase voltage to the bit line, the erase voltage being greater than the GIDL voltage; and
perform one of
applying a third voltage to a third GIDL line that is between the word lines and a source line, the third GIDL line corresponding to the first cell string, the third voltage being greater than the GIDL voltage; or
applying, during a third phase, a fourth voltage to the third GIDL line, and floating, during a fourth phase after the third phase, the third GIDL line.

19. The ferroelectric NAND device of claim 16, wherein the peripheral circuit is configured to:
erase a plurality of first cell strings of the memory block by applying the GIDL voltage to at least one first GIDL line, the plurality of first cell strings comprising the first cell string, the at least one first GIDL line comprising the first GIDL line; and
after erasing the plurality of first cell strings, erase a plurality of second cell strings of the memory block by applying the GIDL voltage to at least one second GIDL line, the plurality of second cell strings comprising the second cell string, the at least one second GIDL line comprising the second GIDL line,
wherein the at least one first GIDL line is isolated from the at least one second GIDL line.

20. A system, comprising:
a ferroelectric NAND device, comprising:
a plurality of memory blocks, a memory block of the plurality of memory blocks comprising a plurality of cell strings including a first cell string and a second cell string; and
a peripheral circuit coupled to the memory block of the plurality of memory blocks, wherein the peripheral circuit is configured to perform an erase operation by:
erasing the first cell string; and
after erasing the first cell string, erasing the second cell string; and
a controller coupled to the ferroelectric NAND device and configured to operate the ferroelectric NAND device.
